(19) United States
(12) Patent Application Publication
(10) Pub. No.: US 2024/0371603 A1
(43) Pub. Date: Nov. 7, 2024

(54) PLASMA PROCESSING APPARATUS, ANALYSIS APPARATUS, PLASMA PROCESSING METHOD, ANALYSIS METHOD, AND STORAGE MEDIUM

(71) Applicant: Tokyo Electron Limited, Tokyo (JP)

(72) Inventor: Kazushi KANEKO, Nirasaki City (JP)

(73) Assignee: Tokyo Electron Limited, Tokyo (JP)

(21) Appl. No.: 18/776,494

(22) Filed: Jul. 18, 2024

Related U.S. Application Data
(63) Continuation of application No. PCT/JP2023/000959, filed on Jan. 16, 2023.

(30) Foreign Application Priority Data
Jan. 18, 2022 (JP) 2022-005975

(51) Int. Cl. H01J 37/32; G05B 13/02; G06N 5/02

(52) U.S. Cl. CPC H01J 37/32165; G05B 13/0265; G06N 5/02

(57) ABSTRACT

A plasma processing apparatus including: an inference part that infers a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

### CROSS-REFERENCE TO RELATED APPLICATIONS

This application is a continuation application of International Patent Application No. PCT/JP2023/000959, filed on Jan. 16, 2023, which claims priority from Japanese Patent Application No. 2022-005975, filed on Jan. 18, 2022, with the Japan Patent Office, the disclosure of each are incorporated herein in its entirety by reference.

### TECHNICAL FIELD

The present disclosure relates to a plasma processing apparatus, an analysis apparatus, a plasma processing method, an analysis method, and a storage medium.

### BACKGROUND

When processing substrates with plasma using a plasma processing apparatus, it is important to minimize the power of reflective waves reflected from a plasma processing space and stabilize the plasma.

In this regard, for example, Japanese Patent Laid-Open Publication No. 2009-246091 discloses a technique of changing the frequency of a bias radio frequency to search for an optimal frequency that minimizes the power of the reflective waves from the plasma processing space.

### SUMMARY

According to an aspect of the present disclosure, a plasma processing apparatus includes: an inference circuitry that infers a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a configuration of a plasma processing apparatus.

FIG. 2 is a view illustrating an example of a configuration of a microwave output device.

FIG. 3 is a view illustrating a hardware configuration of a control device.

FIG. 4 is a view illustrating an example of operation phases of the plasma processing apparatus.

FIG. 5 is a first view illustrating an example of a plasma generation microwave and a bias radio frequency.

FIGS. 6A to 6C are views illustrating a relationship between the frequency or median frequency of the plasma generation microwave and a reflection coefficient.

FIG. 7 is a first view illustrating an example of a functional configuration of the control device in a learning phase.

FIGS. 8A and 8B are first views illustrating a specific example of a learning data generation process.

FIGS. 9A and 8B are second views illustrating a specific example of the learning data generation process.

FIGS. 10A and 10B are third views illustrating a specific example of the learning data generation process.

FIGS. 11A and 11B are fourth views illustrating a specific example of the learning data generation process.

FIG. 12 is a second view illustrating an example of the functional configuration of the control device in the learning phase.

FIG. 13 is a flowchart illustrating the flow of a learning process.

FIG. 14 is a view illustrating an example of the functional configuration of the control device in an inference phase.

FIG. 15 is a flowchart illustrating the flow of an inference process.

FIGS. 16A to 16C are views illustrating a relationship between the set frequency of the plasma generation microwave and reflective wave characteristics.

FIG. 17 is a view illustrating an example of the functional configuration of the control device in an adjustment phase.

FIG. 18 is a first flowchart illustrating the flow of an adjustment process.

FIG. 19 is a second flowchart illustrating the flow of the adjustment process.

FIG. 20 is a third flowchart illustrating the flow of the adjustment process.

FIGS. 21A and 21B are second views illustrating an example of the plasma generation microwave and the bias radio frequency.

FIG. 22 is a third view illustrating an example of the plasma generation microwave and the bias radio frequency.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, each embodiment is described with reference to the accompanying drawings. In the descriptions herein and the drawings, components having substantially the same functional configuration are denoted by the same reference numerals, and overlapping descriptions thereof are omitted.

### First Embodiment

### (Configuration of Plasma Processing Apparatus)

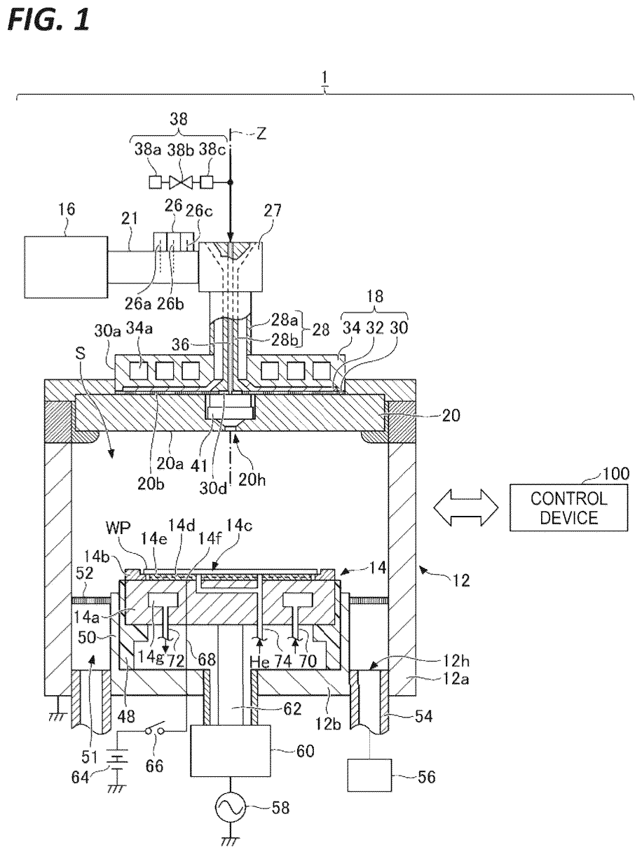

First, the configuration of a plasma processing apparatus according to a first embodiment is described hereinbelow. FIG. 1 is a view illustrating an example of the configuration of the plasma processing apparatus. As illustrated in FIG. 1, a plasma processing apparatus 1 includes a chamber body 12 and a microwave output device 16. Further, the plasma processing apparatus 1 includes a stage 14, an antenna 18, and a dielectric window 20.

The chamber body 12 is provided with a processing space S therein. The chamber body 12 includes a side wall 12a and a bottom 12b. The side wall 12a is formed in a substantially cylindrical shape. The central axis line of the side wall 12a substantially coincides with a vertically extending axis line Z. The bottom 12b is provided at the lower end of the side wall 12a. At the bottom 12b, an exhaust hole 12h is formed. Further, an opening is formed at the upper end of the side wall 12a.

The dielectric window 20 is provided on the upper end of the side wall 12a. The dielectric window 20 includes a lower surface 20a facing the processing space S. The dielectric window 20 closes the opening formed at the upper end of the side wall 12a. An O-ring is interposed between the dielectric window 20 and the upper end of the side wall 12a. By interposing the O-ring, the chamber body 12 is more securely sealed.

The stage 14 is accommodated in the processing space S. The stage 14 is provided to face the dielectric window 20 in the vertical direction. Further, the stage 14 is provided such that the processing space S is sandwiched between the dielectric window 20 and the stage 14. The stage 14 is configured to support a substrate WP placed thereon.

In the present embodiment, the stage 14 includes a base 14a and an electrostatic chuck 14c. The base 14a has a substantially disk shape, and is formed of a conductive material such as aluminum. The central axis line of the base 14a substantially coincides with the axis line Z. The base 14a is supported by a cylindrical support unit 48. The cylindrical support unit 48 is formed of an insulating material, and extends vertically upward from the bottom 12b. A conductive cylindrical support unit 50 is provided around the periphery of the cylindrical support unit 48. The cylindrical support unit 50 extends vertically upward from the bottom 12b of the chamber body 12 along the periphery of the cylindrical support unit 48. An annular exhaust passage 51 is formed between the cylindrical support unit 50 and the side wall 12a.

A baffle plate 52 is provided in the upper part of the exhaust passage 51. The baffle plate 52 has an annular shape. In the baffle plate 52, a plurality of through holes is formed to penetrate the baffle plate 52 in the thickness direction of the plate. The exhaust hole 12h described above is formed below the baffle plate 52. An exhaust device 56 is connected to the exhaust hole 12h via an exhaust pipe 54. The exhaust device 56 includes an automatic pressure control valve and a vacuum pump such as a turbo molecular pump. The exhaust device 56 may reduce the pressure of the processing space S to a desired degree of vacuum.

The base 14a also serves as a radio-frequency electrode. A bias radio-frequency power supply 58 is electrically connected to the base 14a via a power feeding rod 62 and a matching unit 60. The radio-frequency power supply 58 outputs a radio frequency with a certain frequency, e.g., 13.56 MHz, at a set power suitable for controlling the energy of ions to be drawn into the substrate WP.

The radio-frequency power supply 58 may include a pulse generator to pulse-modulate the radio-frequency power (RF power) and apply the pulse-modulated RF power to the substrate 14a. In this case, the radio-frequency power supply 58 pulse-modulates the radio-frequency power to the radio-frequency power, in which a High level power and a Low level power are periodically repeated. The radio-frequency power supply 58 performs a pulse adjustment based on a synchronization signal PSS-R generated by the pulse generator. The synchronization signal PSS-R is a signal that determines the period and the duty ratio of the radio-frequency power. As examples of settings for the pulse modulation, the pulse frequency is 10 Hz to 250 kHz, and the pulse duty ratio (ratio of the time of the High level power to the pulse period) is 10% to 90%.

The matching unit 60 accommodates a matcher that matches the impedance on the side of the radio-frequency power supply 58 and the impedance on a load side, mainly, the electrode, plasma, or the chamber body 12. The matcher includes a blocking capacitor for self-bias generation. The matching unit 60 operates to perform the matching based on the synchronization signal PSS-R, when the radio-frequency power is pulse-modulated.

The electrostatic chuck 14c is provided on the upper surface of the base 14a. The electrostatic chuck 14c holds the substrate WP by an electrostatic adsorption force. The electrostatic chuck 14c includes an electrode 14d, an insulating film 14e, and an insulating film 14f, and has a substantially disk shape. The central axis line of the electrostatic chuck 14c substantially coincides with the axis line Z. The electrode 14d of the electrostatic chuck 14c is configured with a conductive film, and provided between the insulating films 14e and 14f. A DC power supply 64 is electrically connected to the electrode 14d via a switch 66 and a coated wire 68. The electrostatic chuck 14c may adsorb and hold the substrate WP by the Coulomb force generated by a DC voltage applied from the DC power supply 64. Further, a focus ring 14b is provided on the base 14a. The focus ring 14b is disposed to surround the substrate WP and the electrostatic chuck 14c.

A coolant chamber 14g is provided inside the base 14a. For example, the coolant chamber 14g is formed to extend around the axis line Z. A coolant from a chiller unit is supplied to the coolant chamber 14g via a pipe 70. The coolant supplied to the refrigerant chamber 14g is returned to the chiller unit via a pipe 72. The temperature of the coolant is controlled by the chiller unit, so that the temperature of the electrostatic chuck 14c and the temperature of the substrate WP are controlled.

A gas supply line 74 is formed in the stage 14. The gas supply line 74 supplies a heat transfer gas, for example, He gas, to the space between the upper surface of the electrostatic chuck 14c and the back surface of the substrate WP.

The microwave output device 16 outputs a microwave or microwaves to excite a processing gas supplied into the chamber body 12 (e.g., for plasma generation). Throughout this document, the term “microwave” includes both the singular and plural forms thereof. The microwave output device 16 is configured to adjust the frequency, power, and bandwidth of the microwave in a variable manner. The microwave output device 16 may set the bandwidth of the microwave to, for example, zero, thereby generating a microwave with a single frequency. Further, the microwave output device 16 may generate a microwave with a bandwidth having a plurality of frequency components therein. The powers of the plurality of frequency components may be the same, or only the median frequency component within the bandwidth may have a larger power than those of the other frequency components.

As an example, the microwave output device 16 may adjust the power of the microwave in the range of 0 W to 5,000 W. Further, the microwave output device 16 may adjust the frequency or median frequency of the microwave in the range of 2,400 MHz to 2,500 MHz, and the bandwidth of the microwave in the range of 0 MHz to 100 MHz. Further, the microwave output device 16 may adjust the frequency pitches (carrier pitches) of the plurality of frequency components of the microwave within the bandwidth in the range of 0 kHz to 25 kHz.

The microwave output device 16 may include a pulse generator to pulse-modulate and output the power of the microwave. In this case, the microwave output device 16 pulse-modulates the microwave to the power, in which a High level power and a Low level power are periodically repeated. The microwave output device 16 performs a pulse adjustment based on a synchronization signal PSS-M generated by the pulse generator. The synchronization signal PSS-M is a signal that determines the period and the duty ratio of the microwave power. As examples of settings for the pulse modulation, the pulse frequency is 1 Hz to 20 kHz, and the pulse duty ratio (ratio of the time of the High level power to the pulse period) is 10% to 90%. The microwave output device 16 may pulse-modulate the power of the microwave to be synchronized with the pulse-modulated radio-frequency power, which is output by the radio-frequency power supply 58. The detailed configuration of the microwave output device 16 is described herein later. Further, specific examples of the plasma generation microwave, which is output by the microwave output device 16, is described herein later, along with specific examples of the bias radio frequency, which is output by the radio-frequency power supply 58.

The plasma processing apparatus 1 further includes a waveguide 21, a tuner 26, a mode converter 27, and a coaxial waveguide 28. The output unit of the microwave output device 16 is connected to one end of the waveguide 21. The other end of the waveguide 21 is connected to the mode converter 27. The waveguide 21 has, for example, a rectangular shape. The waveguide 21 is provided with the tuner 26. The tuner 26 includes stubs 26a, 26b, and 26c. Each of the stubs 26a, 26b, and 26c is configured to adjust a protrusion amount relative to the interior space of the waveguide 21. The tuner 26 adjusts the protrusion position of each of the stubs 26a, 26b, and 26c relative to a reference position, to match the impedance of the microwave output device 16 and the impedance of a load, e.g., the chamber body 12.

The mode converter 27 converts the mode of the microwave from the waveguide 21, and supplies the mode-converted microwave to the coaxial waveguide 28. The coaxial waveguide 28 includes an outer conductor 28a and an inner conductor 28b. The outer conductor 28a has a substantially cylindrical shape, and the central axis line thereof substantially coincides with the axis line Z. The inner conductor 28b has a substantially cylindrical shape, and extends inside the outer conductor 28a. The central axis line of the inner conductor 28b substantially coincides with the axis line Z. The coaxial waveguide 28 transmits the microwave from the mode converter 27 to the antenna 18.

The antenna 18 is provided on the surface 20b of the dielectric window 20, which is opposite to the lower surface 20a of the dielectric window 20. The antenna 18 includes a slot plate 30, a dielectric plate 32, and a cooling jacket 34.

The slot plate 30 is provided on the surface 20b of the dielectric window 20. The slot plate 30 is formed of a conductive metal, and has a substantially disk shape. The central axis line of the slot plate 30 coincides with the axis line Z. A plurality of slot holes 30a is formed in the slot plate 30. In an example, the plurality of slot holes 30a form a plurality of slot pairs. Each of the plurality of slot pairs includes two slot holes 30a in the shape of the substantially elongated holes that extend in the direction intersecting each other. The plurality of slot pairs are arranged along one or more concentric circles around the axis line Z. A through hole 30d is formed at the center of the slot plate 30, through which a conduit 36, which is described herein below, may pass.

The dielectric plate 32 is provided on the slot plate 30. The dielectric plate 32 is formed of a dielectric material such as quartz, and has a substantially disk shape. The central axis line of the dielectric plate 32 substantially coincides with the axis line Z. The cooling jacket 34 is provided on the dielectric plate 32. The dielectric plate 32 is provided between the cooling jacket 34 and the slot plate 30.

The surface of the cooling jacket 34 has conductive properties. A flow path 34a is formed inside the cooling jacket 34. The flow path 34a is configured to be supplied with coolant. The lower end of the outer conductor 28a is electrically connected to the upper surface of the cooling jacket 34. The lower end of the inner conductor 28b is electrically connected to the slot plate 30 through the cooling jacket 34 and the hole formed at the center of the dielectric plate 32.

The microwave from the coaxial waveguide 28 propagates in the dielectric plate 32, and is supplied to the dielectric window 20 through the plurality of slot holes 30a in the slot plate 30. The microwave supplied to the dielectric window 20 is introduced into the processing space S.

The conduit 36 passes through the inner hole of the inner conductor 28b of the coaxial waveguide 28. As described above, the through hole 30d is formed at the center of the slot plate 30, through which the conduit 36 may pass. The conduit 36 extends through the inner hole of the inner conductor 28b, and is connected to a gas supply system 38.

The gas supply system 38 supplies a processing gas for processing the substrate WP to the conduit 36. The gas supply system 38 includes a gas source 38a, a valve 38b, and a flow controller 38c. The gas source 38a is the gas source of the processing gas. The valve 38b switches the supply of the processing gas from the gas source 38a and the stop of the supply. The flow controller 38c is, for example, a mass flow controller, and adjusts the flow rate of the processing gas from the gas source 38a.

The plasma processing apparatus 1 further includes an injector 41. The injector 41 supplies a gas from the conduit 36 to the through hole 20h formed in the dielectric window 20. The gas supplied to the through hole 20h of the dielectric window 20 is supplied into the processing space S. Then, the gas is excited by the microwave introduced into the processing space S through the dielectric window 20. As a result, plasma is generated in the processing space S, and the substrate WP is processed by active species such as ions and/or radicals from the plasma.

The plasma processing apparatus 1 further includes a control device 100. The control device 100 comprehensively controls each unit of the plasma processing apparatus 1. The details of the hardware configuration and the functional configuration of the control device 100 are described herein below.

### (Details of Configuration of Microwave Output Device)

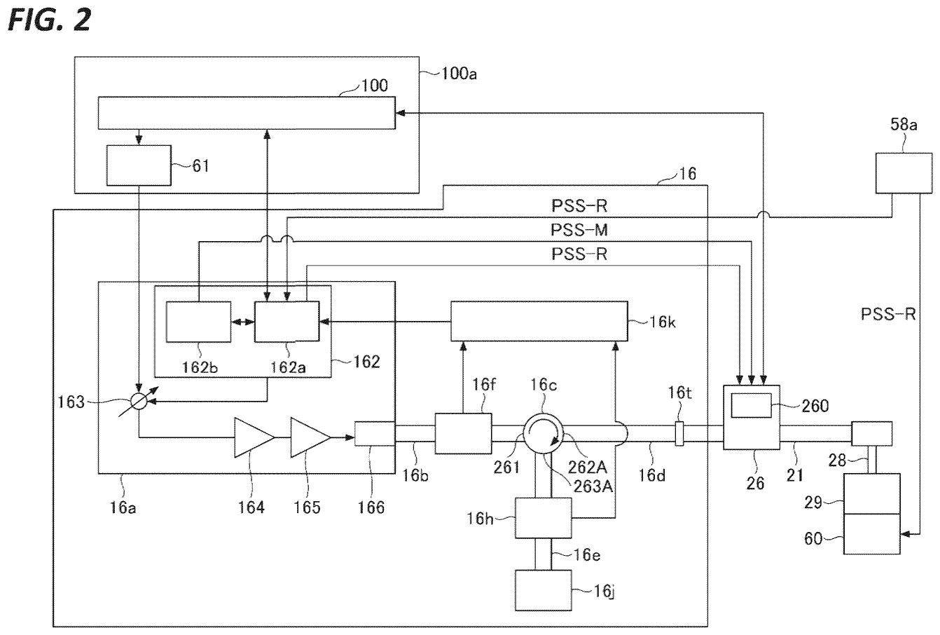

Next, descriptions are made on the details of the configuration of the microwave output device 16 (including the configuration of devices connected to the microwave output device 16) provided in the plasma processing apparatus 1. FIG. 2 is a view illustrating an example of the configuration of the microwave output device. As illustrated in FIG. 2, the microwave output device 16 is connected to an arithmetic device 100a including the control device 100 and a waveform generator 161.

The waveform generator 161 generates a microwave waveform. The waveform generator 161 generates a microwave waveform with a frequency or median frequency and a bandwidth that correspond to a set frequency and a set bandwidth specified by the control device 100, respectively. The waveform generator 161 outputs the microwave waveform to the microwave output device 16.

The microwave output device 16 pulse-modulates the microwave waveform generated by the waveform generator 161 according to the settings of the control device 100, and outputs the pulse-modulated microwave waveform as a microwave. The microwave output device 16 includes a microwave generation unit 16a, a waveguide 16b, a circulator 16c, a waveguide 16d, a waveguide 16e, a first directional coupler 16f, a second directional coupler 16h, a measurement unit 16k, and a dummy load 16j.

The microwave generation unit 16a generates the microwave, of which power is pulse-modulated to meet the pulse frequency, the set pulse duty ratio, the set power of the High level and the Low level that are instructed by the control device 100.

The microwave generation unit 16a includes a power control unit 162, an attenuator 163, an amplifier 164, an amplifier 165, and a mode converter 166 (corresponding to the mode converter 27 in FIG. 1).

The waveform generation unit 161 is connected to the attenuator 163. The attenuator 163 is, for example, a device that may change an attenuation amount according to an applied voltage value. The power control unit 162 is connected to the attenuator 163. The power control unit 162 controls the attenuation amount of the microwave in the attenuator 163 by using the applied voltage value. The power control unit 162 controls the attenuation amount in the attenuator 163, such that the microwave output by the waveform generation unit 161 meets the pulse frequency, the set pulse duty ratio, and the set power of the High level and the Low level, that are instructed by the control device 100.

The power control unit 162 includes, for example, a control unit 162a and a pulse generator 162b. The control unit 162a acquires a setting profile from the control device 100. The control unit 162a outputs information necessary for the pulse modulation (pulse frequency and set pulse duty ratio) from the setting profile to the pulse generator 162b. The pulse generator 162b generates the synchronization signal PSS-M based on the acquired information. Based on the synchronization signal PSS-M and the setting profile set by the control device 100, the control unit 162a determines the attenuation amount of the microwave.

The control unit 162a may acquire the synchronization signal PSS-R generated from the pulse generator 58a of the radio-frequency power supply 58. The pulse generator 162b may generate the synchronization signal PSS-M synchronized with the synchronization signal PSS-R. In this case, the pulse modulation of the microwave power and the pulse modulation of the radio-frequency power may be synchronized with each other.

The output of the attenuator 163 is connected to the mode converter 166 via the amplifiers 164 and 165. The amplifiers 164 and 165 each amplify the microwave at a predetermined amplification rate. The mode converter 166 converts the propagation mode of the microwave output from the amplifier 165 from TEM to TE01. The microwave generated by the mode conversion in the mode converter 166 is output as an output microwave of the microwave generation unit 16a.

The output of the microwave generation unit 16a is connected to one end of the waveguide 16b. The other end of the waveguide 16b is connected to a first port 261 of the circulator 16c. The circulator 16c has a first port 261, a second port 262A, and a third port 263A. The circulator 16c is configured to output the microwave input to the first port 261 from the second port 262A, and output the microwave input to the second port 262A from the third port 263A. One end of the waveguide 16d is connected to the second port 262A of the circulator 16c. The other end of the waveguide 16d is an output unit 16t of the microwave output device 16.

One end of the waveguide 16b is connected to the third port 263A of the circulator 16c. The other end of the waveguide 16e is connected to the dummy load 16j. The dummy load 16j receives the microwave propagating through the waveguide 16e, and absorbs the microwave. The dummy load 16j converts the microwave into, for example, heat.

The first directional coupler 16f is provided between one end and the other end of the waveguide 16b. The first directional coupler 16f is configured to split a portion of the microwave output from the microwave generation unit 16a and propagating to the output unit 16t (e.g., a traveling wave), and output the portion of the traveling wave.

The second directional coupler 16h is provided between one end and the other end of the waveguide 16e. For the microwave returned to the output unit 16t (e.g., a reflective wave), the second directional coupler 16h is configured to split a portion of the reflective wave transmitted to the third port 263A of the circulator 16c, and output the portion of the reflective wave.

Based on the portion of the traveling wave output from the first directional coupler 16f, the measurement unit 16k determines a first High measurement value p_{f}(H) and a first Low measurement value p_{f}(L) that indicate the High level and the Low level of the power of the traveling wave in the output unit 16t, respectively. Further, based on the portion of the reflective wave output from the second directional coupler 16h, the measurement unit 16k determines a second High measurement value pᵣ(H) and a second Low measurement value pᵣ(L) that indicate the High level and the Low level of the power of the reflective wave in the output unit 16t, respectively.

The measurement unit 16k is connected to the power control unit 162. The measurement unit 16k outputs the measurement values to the power control unit 162. The power control unit 162 controls the attenuator 163 such that the difference between the measurement values of the traveling wave and the reflective wave, e.g., a load power (effective power), matches the set power specified by the control device 100 (power feedback control).

The tuner 26 includes a tuner control unit 260. The tuner control unit 260 adjusts the protrusion positions of the stubs 26a, 26b, and 26c to match the impedance on the side of the microwave output device 16 and the impedance on the side of the antenna 18 with each other, based on signals from the control device 100. The tuner control unit 260 operates the stubs 26a, 26b, and 26c by using driver circuits and actuators (not illustrated).

The tuner control unit 260 may acquire at least one of the synchronization signal PSS-M for the microwave power, which is generated by the pulse generator 162b, and the synchronization signal PSS-R for the radio-frequency power, which is generated by the pulse generator 58a of the radio-frequency power supply 58. For example, the tuner control unit 260 acquires the synchronization signal PSS-M from the control unit 162a. The tuner control unit 260 may acquire the synchronization signal PSS-R from the control unit 162a or directly from the pulse generator 58a of the radio-frequency power supply 58. The tuner control unit 260 may operate the stubs 26a, 26b, and 26c in consideration of the synchronization signals.

### (Hardware Configuration of Control Device)

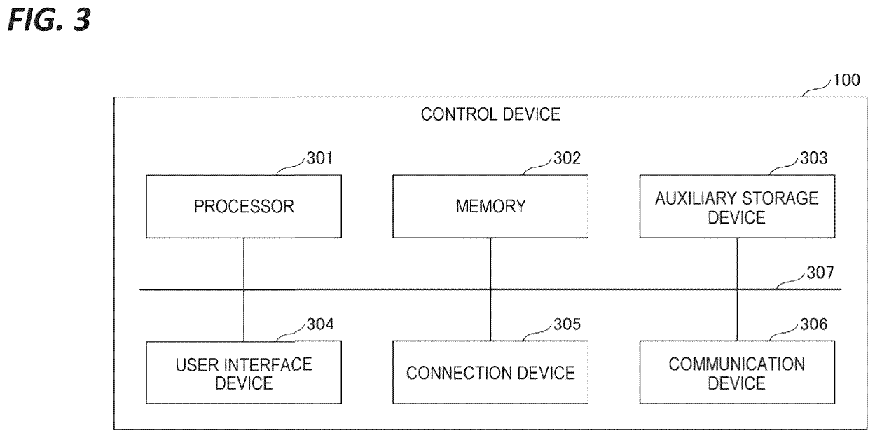

Next, the hardware configuration of the control device 100 provided in the plasma processing apparatus 1 is described. FIG. 3 is a view illustrating an example of the hardware configuration of the control device. As illustrated in FIG. 3, the control device 100 includes a processor 301, a memory 302, an auxiliary storage device 303, a user interface device 304, a connection device 305, and a communication device 306. The hardware components of the control device 100 are connected to each other via a bus 307.

The processor 301 includes various arithmetic devices such as a central processing unit (CPU) and a graphics processing unit (GPU). The processor 301 reads and executes various programs (e.g., a plasma processing program according to the present embodiment, as well as a program for comprehensively controlling each unit of the plasma processing apparatus 1) on the memory 302.

The memory 302 includes main storage devices such as a read only memory (ROM) and a random access memory (RAM). The processor 301 and the memory 302 form a computer, and the processor 301 executes the various programs read on the memory 302 to implement various functions of the computer.

The auxiliary storage device 303 stores various programs, or various data used when the various programs are executed by the processor 301.

The user interface device 304 includes, for example, a keyboard or a touch panel, with which a process manager performs, for example, an input operation of commands in order to manage the plasma processing apparatus 1, and a display that visually displays, for example, an operation status of the plasma processing apparatus 1.

The connection device 305 is a connection device that is connected to, for example, the microwave output device 16, the stage 14, the gas supply system 38, and the exhaust device 56, which are examples of the units of the plasma processing apparatus 1.

The communication device 306 is a communication device for communicating with an external device (not illustrated) through a network.

### (Operation Phases of Plasma Processing Apparatus)

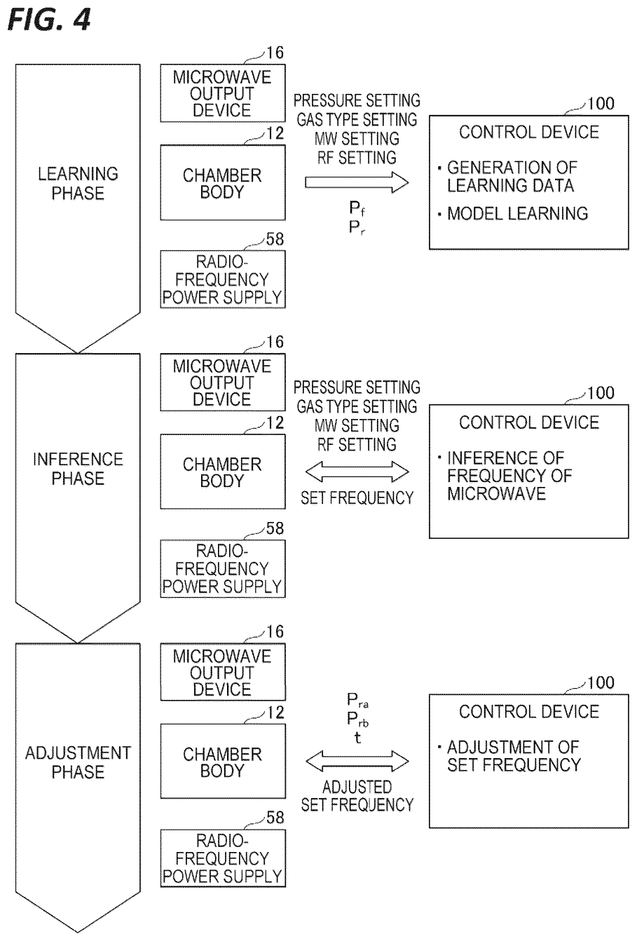

Next, the operation phases of the plasma processing apparatus 1 are described. FIG. 4 is a view illustrating an example of the operation phases of the plasma processing apparatus. As illustrated in FIG. 4, in the present embodiment, the plasma processing apparatus 1 operates by any one operation phase of a learning phase, an inference phase, and an adjustment phase.

Among the operation phases, the learning phase is a phase in which the control device 100 executes a learning about the set frequency in order to optimize the frequency or median frequency of the microwave output by the microwave output device 16.

In the learning phase, the control device 100 acquires processing conditions when a plasma processing is performed. Further, in the learning phase, the control device 100 acquires a reflection coefficient based on the power of the reflective wave from the processing space S of the chamber body 12, which is measured when the microwave output device 16 outputs the microwave under each set frequency while changing the set frequency. Here, the processing conditions acquired by the control device 100 include, for example,
setting of the pressure in the processing space S (pressure setting),
setting of the type of gas supplied into the processing space S (gas type setting),
setting when the microwave output device 16 outputs the plasma generation microwave (MW setting), and
setting when the radio-frequency power supply 58 outputs the bias radio frequency (RF setting). Further, the setting when the microwave output device 16 outputs the plasma generation microwave (MW setting) includes, for example,
set frequency of the microwave,
set bandwidth of the microwave, carrier frequencies of a plurality of frequency components of the microwave within the bandwidth, and
when the power of the microwave is pulse-modulated, set pulse frequency, set pulse duty ratio, and set power of the High level and the Low level of the pulse. Further, the setting when the radio-frequency power supply 58 outputs the bias radio frequency (RF setting) includes, for example,
set frequency of the radio frequency, and
when the power of the radio frequency is pulse-modulated, set pulse frequency, set pulse duty ratio, set power of the High level and the Low level of the pulse, and an offset.

The reflection coefficient is based on the power of the reflective wave acquired by the control device 100, and includes, for example, a reflection coefficient Γ_{load} calculated based on the ratio of the power P_{f} of the traveling wave of the microwave and the power Pᵣ of the reflective wave of the microwave. The power P_{f} of the traveling wave of the microwave is measured as each of a first High measurement value p_{f}(H) for the High level of the pulse and a first Low measurement value p_{f}(L) for the Low level of the pulse. The power Pᵣ of the reflective wave of the microwave is measured as each of a second High measurement value pᵣ(H) for the High level of the pulse and a second Low measurement value pᵣ(L) for the Low level of the pulse. The reflection coefficient of the High level is the square root of a value obtained by dividing the second High measurement value pᵣ(H) by the first High measurement value p_{f}(H). The reflection coefficient of the Low level is the square root of a value obtained by dividing the second Low measurement value pᵣ(L) by the first Low measurement value p_{f}(L).

In the learning phase, the control device 100 determines the smallest reflection coefficient among the reflection coefficients calculated based on the power of the acquired reflective wave. Thus, the control device 100 may identify the optimal set frequency that minimizes the reflection coefficient.

Further, in the learning phase, the control device 100 associates each of the plurality of acquired processing conditions (excluding the set frequency of the microwave) with the optimal set frequency that minimizes the reflection coefficient. Accordingly, the control device 100 may generate learning data that include each of the acquired processing conditions (excluding the set frequency of the microwave) as input data and the optimal set frequency that minimizes the reflection coefficient as correct data. Further, the control device 100 may perform a model learning using the generated learning data.

Subsequently, in the inference phase, the control device 100 acquires the processing conditions when the plasma processing is performed. The items of the processing conditions acquired at this time are the same as the items of the processing conditions acquired by the control device 100 in the learning phase (excluding the set frequency of the microwave).

Further, in the inference phase, the control device 100 inputs the acquired processing conditions into the learned model that has been trained in the learning phase, to infer the set frequency of the microwave that minimizes the reflection coefficient. Further, in the inference phase, the control device 100 instructs the microwave output device 16 to output the plasma generation microwave under the inferred set frequency.

Subsequently, in the adjustment phase, the control device 100 acquires reflective wave characteristics measured during the execution of the plasma processing. The reflective wave characteristics acquired by the control device 100 are the characteristics of the reflective wave reflected from the processing space S of the chamber body 12 when the microwave output device 16 outputs the plasma generation microwave under the set frequency specified by the control device 100, and include, for example,
maximum reflection power Pᵣₐ at the start time of pulse,
maximum reflection power P_{rb} at the stable time of pulse, and
stable reflection time “t,”

Further, in the adjustment phase, the control device 100 finely adjusts the set frequency (addition or subtraction by k_{f}) based on the acquired reflective wave characteristics, and specifies an adjusted set frequency. In this way, in the adjustment phase, the control device 100 monitors whether the reflective wave characteristics are improved by the fine adjustment of the set frequency. Further, in the adjustment phase, when the reflective wave characteristics are improved as a result of the fine adjustment of the set frequency by the control device 100, the microwave output device 16 outputs the plasma generation microwave under the adjusted set frequency at a later time.

While not illustrated in FIG. 4, a re-learning phase may be provided after the adjustment phase. Specifically, in the re-learning phase, the control device 100 acquires the adjusted set frequency that has been finely adjusted in the adjustment phase and the corresponding processing conditions thereof (excluding the set frequency of the microwave), and updates the learning data. Further, in the re-learning phase, the control device 100 performs a re-learning process on the learned model by using the updated learning data.

### (Specific Examples of Plasma Generation Microwave and Bias Radio Frequency)

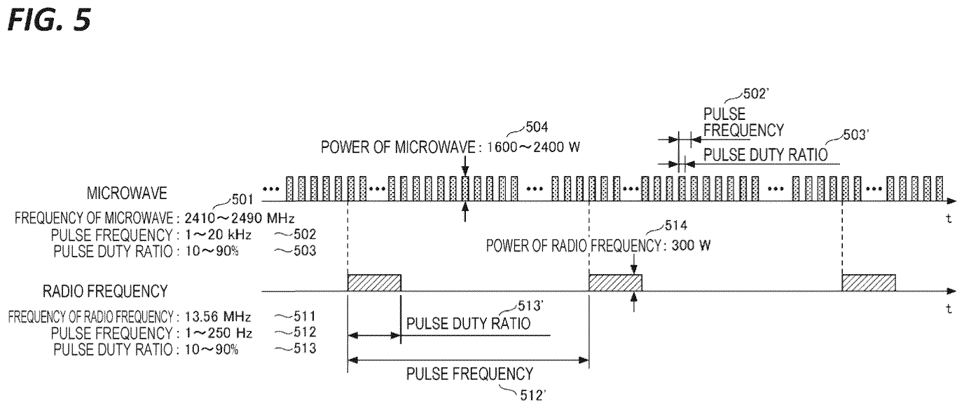

Next, specific examples of the plasma generation microwave and the bias radio frequency are described with reference to FIG. 5. FIG. 5 is a first view illustrating an example of the plasma generation microwave and the bias radio frequency.

In FIG. 5, the upper part represents a pulse signal when the power of the microwave is pulse-modulated, and the lower part represents a pulse signal when the power of the radio frequency is pulse-modulated.

In the example of the upper part of FIG. 5,
The frequency or median frequency of the microwave is any one of 2,410 MHz to 2,490 MHz (reference number 501).
The pulse frequency when the power of the microwave is pulse-modulated is any one of 1 kHz to 20 kHz (reference numeral 502). Here, the pulse frequency is the reciprocal of the time length indicated in the reference numeral 502′.
The pulse duty ratio is any one of 10% to 90% (reference numeral 503). Here, the pulse duty ratio is the ratio of the time length indicated in the reference numeral 503′ to the time length indicated in the reference numeral 502′.
The power of the microwave is any one of 1,600 W to 2,400 W (reference numeral 504).

In the example of the lower part of FIG. 5,
The frequency of the radio frequency is 13.56 MHz (reference numeral 511).
The pulse frequency when the power of the radio frequency is pulse-modulated is any one of 1 Hz to 250 Hz (reference numeral 512). Here, the pulse frequency is the reciprocal of the time length indicated in the reference numeral 512′.
The pulse duty ratio is any one of 10% to 90% (reference numeral 513). Here, the pulse duty ratio is the ratio of the time length indicated in the reference numeral 513′ to the time length indicated in the reference numeral 512′.
The power of the radio frequency is 300 W (reference numeral 514).
   (Relationship between Frequency or Median Frequency of Microwave and Reflection Coefficient)

Next, descriptions are made on the relationship between the reflection coefficient, which is calculated based on the power of the reflective wave measured when the microwave output device 16 outputs the microwave while changing the frequency or median frequency of the microwave, and each frequency.

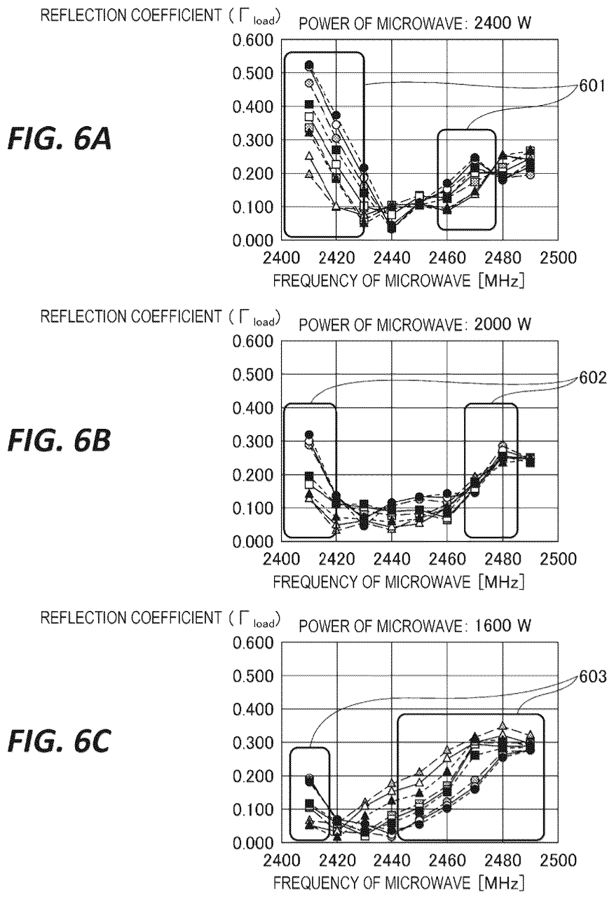

FIGS. 6A to 6C are views illustrating the relationship between the frequency or median frequency of the plasma generation microwave and the reflection coefficient. In FIGS. 6A to 6C, the horizontal axis represents each frequency or median frequency when the microwave output device 16 outputs the microwave. As described above, since the frequency or median frequency of the microwave may be changed in the range of 2,410 MHz to 2,490 MHz, the horizontal axis includes the range of 2,410 MHz to 2,490 MHz.

The vertical axis represents the reflection coefficient F_{load}, which is calculated based on the power of the reflective wave measured when the microwave output device 16 outputs the microwave while changing the frequency or median frequency of the microwave.

The example of FIG. 6A represents a case where the power of the microwave is 2,400 W, the example of FIG. 6B represents a case where the power of the microwave is 2,000 W, and the example of FIG. 6C represents a case where the power of the microwave is 1,600 W. Each of FIGS. 6A to 6C includes a plurality of broken lines indicating that microwaves are output at different pulse frequencies or pulse duty ratios.

As illustrated in FIGS. 6A to 6C, the reflection coefficient Γ_{load} changes when the frequency or median frequency of the microwave is changed. Here, in order to stabilize the plasma in the plasma processing, it is important to specify
the set frequency of the microwave that minimizes the reflection coefficient Γ_{load}, or
the set frequency of the microwave that prevents the steep change of the reflection coefficient Γ_{load} when the frequency or median frequency of the microwave is changed.

In FIGS. 6A to 6C, all of the ranges indicated by the reference numerals 601 to 603 may not be considered as appropriate set frequencies for stabilizing the plasma, because the reflection coefficient Γ_{load} steeply changes when the frequency or median frequency of the microwave is changed. Meanwhile, in FIGS. 6A to 6C, all of the range between the reference numerals 601, the range between the reference numerals 602, and the range between the reference numerals 603 are ranges in which the reflection coefficient Γ_{load} does not steeply change when the frequency or median frequency of the microwave is changed.

Meanwhile, as illustrated in FIGS. 6A to 6C, the set frequency of the microwave that minimizes the reflection coefficient Γ_{load} varies, since the processing conditions (e.g., the power of the microwave, the pulse frequency, and the pulse duty ratio in the examples of FIGS. 6A to 6C) are different.

Thus, in the learning phase, the control device 100 according to the present disclosure collects the optimal set frequency of the microwave for stabilizing the plasma under the various processing conditions, to generate the learning data and perform the model learning.

Thus, hereinafter, descriptions are first made on specific examples of the functional configuration of the control device 00 in the learning phase (e.g., functional configuration for generating the learning data and functional configuration for performing the model learning), and each process (e.g., a learning data generation process and a learning process).

### (Description of Control Device in Learning Phase)

### (1-1) Functional Configuration of Control Device for Generating Learning Data

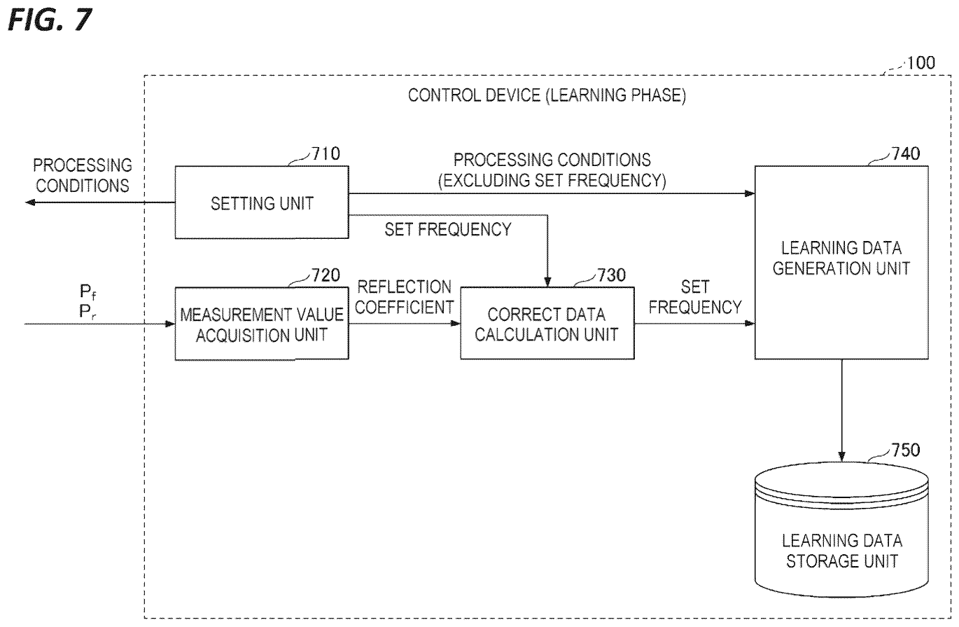

First, the functional configuration of the control device 100 for generating the learning data is described. FIG. 7 is a first view illustrating an example of the functional configuration of the control device in the learning phase. As described above, the plasma processing program is installed in the control unit 100, and executed in the learning phase so that the control device 100 implements the functions to generate the learning data. As illustrated in FIG. 7, the functions to generate the learning data include a setting unit 710, a measurement value acquisition unit 720, a correct data calculation unit 730, and a learning data generation unit 740.

The setting unit 710 sets the processing conditions for performing the plasma processing for each unit of the plasma processing apparatus 1 to instruct the plasma processing, and notifies the processing conditions (excluding the set frequency of the microwave) to the learning data generation unit 740. Further, the setting unit 710 changes the set frequency to change the frequency or median frequency of the plasma generation microwave output by the microwave output device 16, and notifies each set frequency to the correct data calculation unit 730.

During the execution of the plasma processing, the measurement value acquisition unit 720 acquires the power P_{f} of the traveling wave of the microwave and the power Pᵣ of the reflective wave of the microwave, which are measured each time the microwave output device 16 changes the frequency or median frequency of the microwave. The measurement value acquisition unit 720 calculates the reflection coefficient Γ_{load} based on the acquired power P_{f} of the traveling wave of the microwave and power Pᵣ of the reflective wave of the microwave, and notifies the calculated reflection coefficient Γ_{load} to the correct data calculation unit 730.

From each reflection coefficient Γ_{load} notified from the measurement value acquisition unit 720 in association with each set frequency of the microwave, the correct data calculation unit 730 determines:
the set frequency of the microwave that minimizes the reflection coefficient Γ_{load}, or
the set frequency of the microwave that prevents the steep change of the reflection coefficient Γ_{load} when the frequency or median frequency of the microwave is changed, and notifies the determined set frequency to the learning data generation unit 740.

The learning data generation unit 740 stores the processing conditions notified from the setting unit 710 (excluding the set frequency of the microwave) and the reflection coefficient Γ_{load} notified from the correct data calculation unit 730 in association with each other, as learning data in the learning data storage unit 750.

### (1-2) Specific Example 1 of Learning Data Generation Process

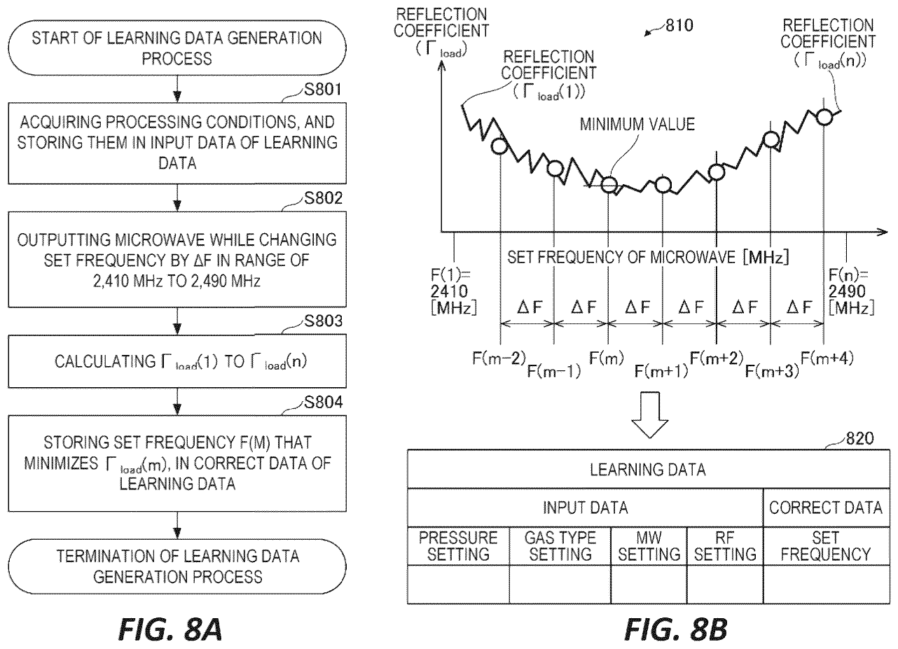

Next, a specific example of the learning data generation process by the control device 100 is described. FIGS. 8A and 8B are first views illustrating a specific example of the learning data generation process. FIG. 8A is a flowchart illustrating the flow of the learning data generation process, and FIG. 8B illustrates specific examples of reflection coefficients acquired during the learning data generation process and learning data generated during the same process.

In step S801, the setting unit 710 of the control device 100 acquires the processing conditions (excluding the set frequency of the microwave). Further, the learning data generation unit 740 of the control device 100 stores the processing conditions (excluding the set frequency of the microwave) in “input data” of learning data 820.

In step S802, the setting unit 710 of the control device 100 instructs the microwave output device 16 to divide the range of F(1) MHz to F(n) MHz into “n” equal parts (“n” is any integer), and output the microwave while changing the set frequency by ΔF. In this case, ΔF=(F(n)−F(1))/n. In the figures, F(1)=2,410 MHz, and F(n)=2,490 MHz.

In step S803, the measurement value acquisition unit 720 of the control device 100 acquires the power P_{f} of the traveling wave of the microwave and the power Pᵣ of the reflective wave of the microwave, each time the set frequency of the microwave is changed by ΔF. Then, the measurement value acquisition unit 720 of the control device 100 calculates the reflection coefficients Γ_{load}(1) to Γ_{load}(n) for the set frequencies F(1) to F(n), and stores the set frequency F(f) and F_{load}(f) in correlation with each other in the memory 302 (see, e.g., the graph 810). Here, “f” is any one integer from 1 to n.

In step S804, the correct data calculation unit 730 of the control device 100 determines the smallest reflection coefficient Γ_{load}(m) among the reflection coefficients Γ_{load}(1) to Γ_{load}(n). Further, the correct data calculation unit 730 of the control device 100 stores the set frequency F(m) corresponding to the smallest reflection coefficient Γ_{load}(m) as “correct data” of the learning data 820.

### (1-3) Specific Example 2 of Learning Data Generation Process

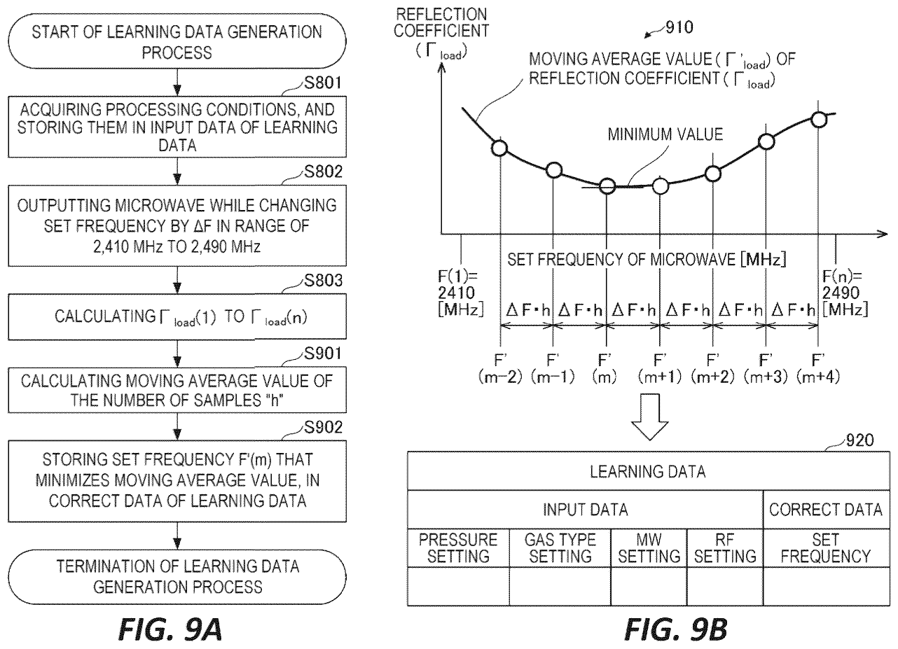

Next, another specific example of the learning data generation process by the control device 100 is described. FIGS. 9A and 9B are second views illustrating a specific example of the learning data generation process. FIG. 9A is a flowchart illustrating the flow of the learning data generation process, and FIG. 9B illustrates specific examples of a moving average value of reflection coefficients calculated during the learning data generation process and learning data generated during the same process.

Since the processes of steps S801 to S803 have been described using FIGS. 8A and 8B, the descriptions thereof are omitted here.

In step S901, when the number of samples to be averaged (frequency width) is “h” for the calculated reflection coefficients Γ_{load}(1) to Γ_{load}(n),
first, the measurement value acquisition unit 720 of the control device 100 averages the reflection coefficients Γ_{load}(1) to Γ_{load}(h), which correspond to F(1) to F(h) when the frequency is F(1), and stores F′(1) and Γ′_{load}(1) in correlation with each other in the memory 302.
Subsequently, the measurement value acquisition unit 720 of the control device 100 averages the reflection coefficients Γ_{load}(2) to Γ_{load}(h+1), which correspond to F(2) to F(h+1) when the frequency is F(2), and stores F′(2) and Γ′_{load}(2) in correlation with each other in the memory 302.
Similarly, the measurement value acquisition unit 720 of the control device 100 averages the reflection coefficients Γ_{load}(n−h) to Γ_{load}(n), which correspond to F′(n−h) to F(n) when the frequency is F(n−h), and stores F′(n−h) and Γ′_{load}(n−h) in correlation with each other in the memory 302 (see, e.g., the graph 910).

As a result, the moving average value Γ′_{load}(f) of the reflection coefficient for the frequency F′(f) may be recalled from the memory 302.

In step S902, the correct data calculation unit 730 of the control device 100 identifies the smallest moving average value Γ′_{load}(m) of the reflection coefficient among the calculated moving average values Γ′_{load}(1) to Γ′_{load}(n−h) of the reflection coefficients. Further, the correct data calculation unit 730 of the control device 100 stores the set frequency F′(m) corresponding to the identified moving average value Γ′_{load}(m) of the reflection coefficient in “correct data” of the learning data 920.

### (1-4) Specific Example 3 of Learning Data Generation Process

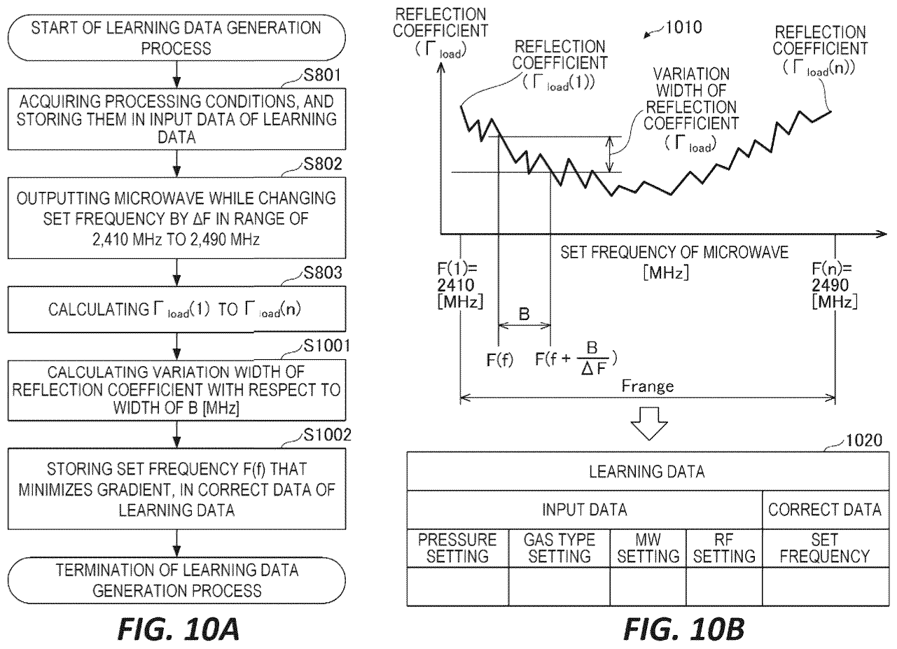

Next, yet another specific example of the learning data generation process by the control device 100 is described. FIGS. 10A and 10B are third views illustrating a specific example of the learning data generation process. FIG. 10A is a flowchart illustrating the flow of the learning data generation process, and FIG. 10B illustrates specific examples of reflection coefficients acquired during the learning data generation process and learning data generated during the same process.

Since the processes of steps S801 to S803 have been described using FIGS. 8A and 8B, the descriptions thereof are omitted here.

In step S1001, for the calculated reflection coefficients Γ_{load}(1) to Γ_{load}(n), the measurement value acquisition unit 720 of the control device 100
extracts reflection coefficients Γ_{load}(f) to Γ_{load}(f+B/ΔF) for the frequencies F(f) to F(f+B/ΔF) having the width of B [MHz],
calculates the difference between the maximum and minimum values as a variation width of a reflection coefficient (i.e., gradient), and
stores F(f) and the variation width of Γ_{load}(f) in correlation with each other (see, e.g., the graph 1010).

B/ΔF is an integer, and is, for example, obtained by truncating decimal parts.

In step S1002, the correct data calculation unit 730 of the control device 100 stores the set frequency F(f) that minimizes the calculated gradient, in “correct data” of learning data 1020.

### (1-5) Specific Example 4 of Learning Data Generation Process

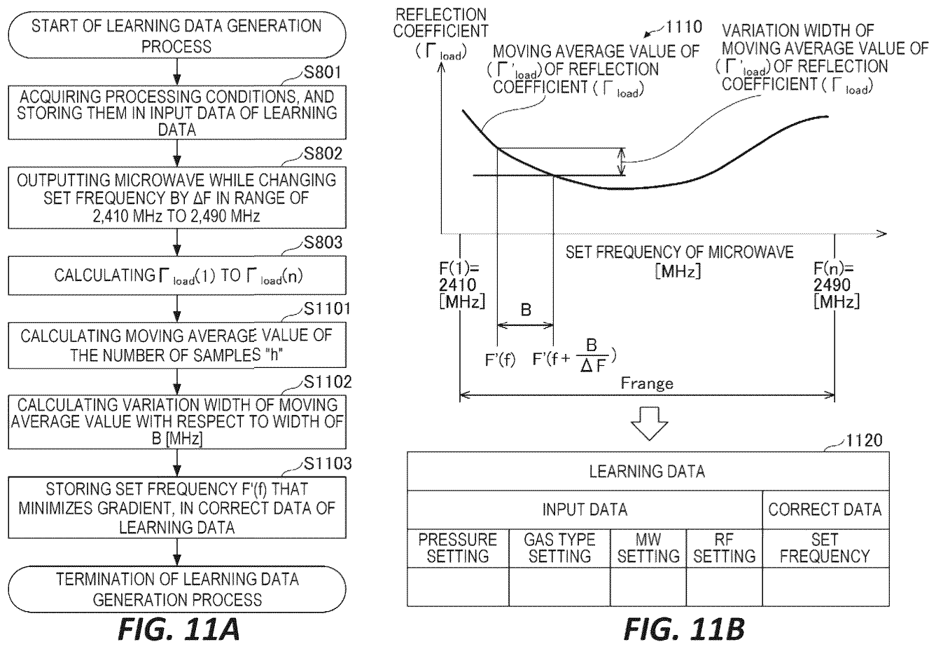

Next, still yet another specific example of the learning data generation process by the control device 100 is described. FIGS. 11A and 11B are fourth views illustrating a specific example of the learning data generation process. FIG. 11A is a flowchart illustrating the flow of the learning data generation process, and FIG. 11B illustrates specific examples of a moving average value of reflection coefficients calculated during the learning data generation process and learning data generated during the same process.

Since the processes of steps S801 to S803 have been described using FIGS. 8A and 8B, the descriptions thereof are omitted here.

In step S1101, when the number of samples to be averaged (frequency width) is “h” for the calculated reflection coefficients Γ_{load}(1) to Γ_{load}(n),
first, the measurement value acquisition unit 720 of the control device 100 averages the reflection coefficients Γ_{load}(1) to Γ_{load}(h), which correspond to F(1) to F(h) when the frequency is F(1), and stores F′(1) and Γ′_{load}(1) in correlation with each other in the memory 302.
Subsequently, the measurement value acquisition unit 720 of the control device 100 averages the reflection coefficients Γ_{load}(2) to Γ_{load}(h+1), which correspond to F(2) to F(h+1) when the frequency is F(2), and stores F′(2) and Γ′_{load}(2) in correlation with each other in the memory 302.
Similarly, the measurement value acquisition unit 720 of the control device 100 averages the reflection coefficients F_{load}(n−h) to Γ_{load}(n), which correspond to F′(n−h) to F(n) when the frequency is F(n−h), and stores F′(n−h) and F′_{load}(n−h) in correlation with each other in the memory 302.

As a result, the moving average value Γ′_{load}(f) of the reflection coefficient for the frequency F′(f) may be recalled from the memory 302.

In step S1102, for the calculated moving average values Γ′_{load}(1) to Γ′_{load}(n) of the reflection coefficients, the measurement value acquisition unit 720 of the control device 100:
extracts moving average values Γ′_{load}(f) to Γ′_{load}(f+B/ΔF) of reflection coefficients for the frequencies F′(f) to F′(f+B/ΔF) having the width of B [MHz],
calculates the difference between the maximum and minimum values as a variation width of a reflection coefficient (i.e., gradient), and
stores F′(f) and the variation width of Γ′_{load}(f) in correlation with each other (see, e.g., the graph 1110). B/ΔF is an integer, and is, for example, obtained by truncating decimal parts.

In step S1103, the correct data calculation unit 730 of the control device 100 stores the set frequency F′(f) that minimizes the calculated gradient, in “correct data” of learning data 1120.

### (2-1) Functional Configuration to Perform Model Learning

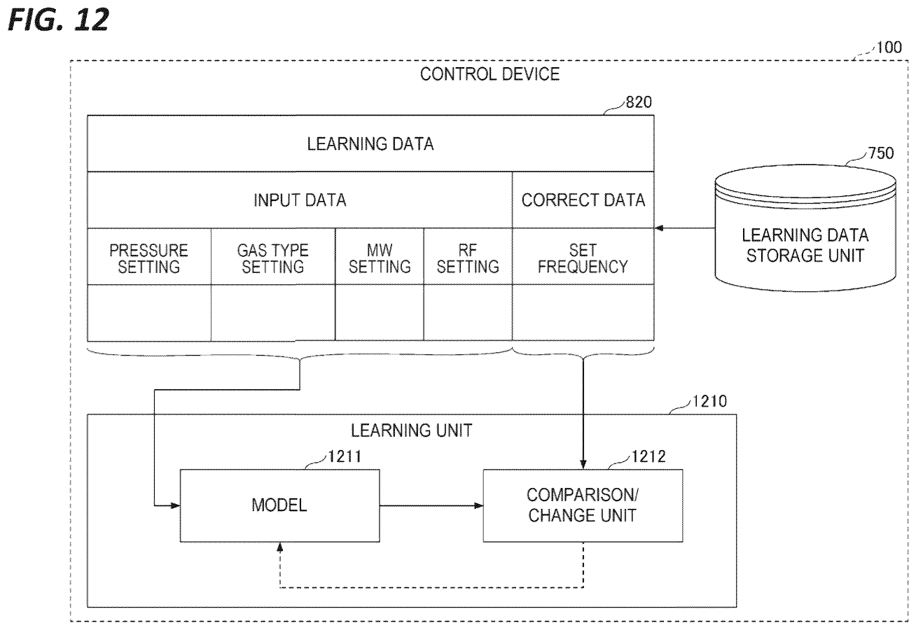

Next, the functional configuration of the control device 100 for performing the model learning is described. FIG. 12 is a second view illustrating an example of the functional configuration of the control device in the learning phase. As described above, the plasma processing program is installed in the control device 100, and when the program is executed in the learning phase, the control device 100 implements the functions to perform the model learning. As illustrated in FIG. 12, the functions to perform the model learning include a learning unit 1210.

The learning unit 1210 includes a model 1211 and a comparison/change unit 1212. The model 1211 is input with input data of the learning data stored in the learning data storage unit 750 (the learning data 820 in the example of FIG. 12). The model 1211 outputs output data when the input data is input into the model 1211.

The comparison/change unit 1212 reads the correct data of the learning data stored in the learning data storage unit 750 (the learning data 820 in the example of FIG. 12), and calculates the difference between the correct data and the output data output from the model 1211. Then, the comparison/change unit 1212 updates model parameters of the model 1211 such that the calculated difference approaches zero. The learning unit 1210 continues the “learning” to update the model parameters of the model 1211 until a predetermined termination condition is satisfied. When the predetermined termination condition is satisfied, the model for which the learning has been terminated is set as a learned model in an inference unit to be described herein below.

### (2-2) Flow of Learning Process

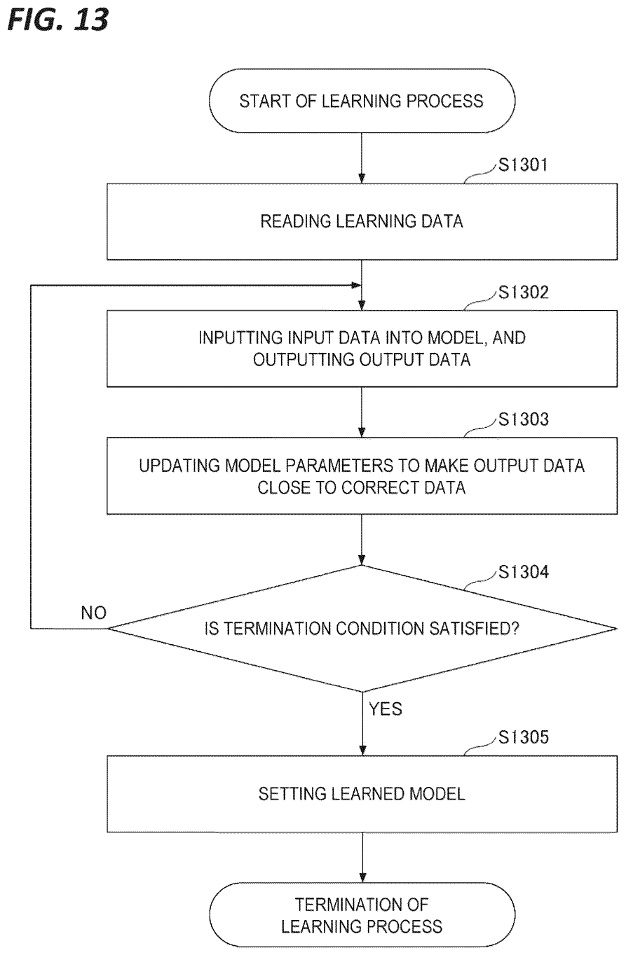

Next, the flow of the learning process by the control device 100 is described. FIG. 13 is a flowchart illustrating the flow of the learning process.

In step S1301, the learning unit 1210 of the control device 100 reads the learning data from the learning data storage unit 750.

In step S1302, the learning unit 1210 of the control device 100 inputs the input data of the learning data into the model 1211. In response, the model 1211 outputs the output data.

In step S1303, the comparison/change unit 1212 of the control device 100 updates the model parameters of the model 1211 such that the output data become close to the correct data.

In step S1304, the learning unit 1210 of the control device 100 determines whether the predetermined termination condition is satisfied. When it is determined in step S1304 that the predetermined termination condition is not satisfied (NO in step S1304), the process returns to step S1302.

Meanwhile, when it is determined in step S1304 that the predetermined termination condition is satisfied (YES in step S1304), the process proceeds to step S1305.

In step S1305, the learning unit 1210 of the control device 100 sets the model parameters of the learned model as a learned model in the inference unit (to be described herein below).

### (Description of Control Device in Inference Phase)

### (1) Functional Configuration of Control Device in Inference Phase

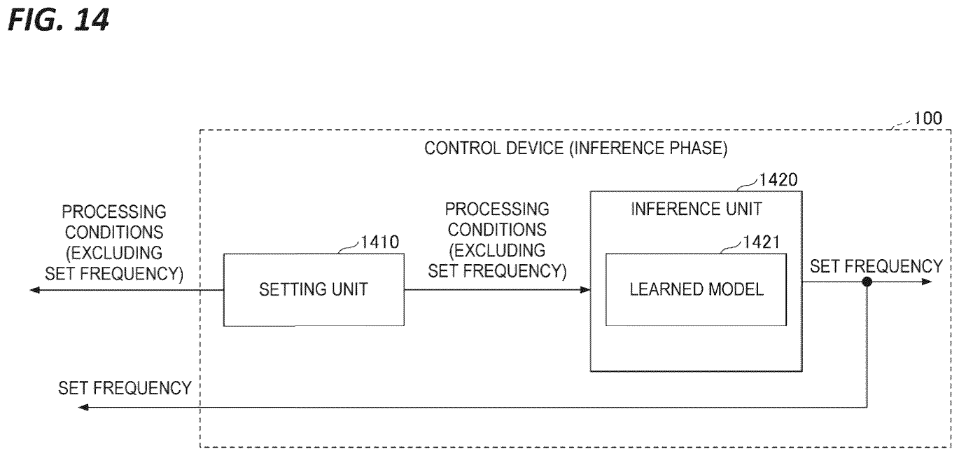

Next, the functional configuration of the control device 100 in the inference phase is described. FIG. 14 is a view illustrating an example of the functional configuration of the control device in the inference phase. As described above, the plasma processing program is installed in the control device 100, and when the program is executed in the inference phase, the control device 100 functions as a setting unit 1410 and an inference unit 1420 as illustrated in FIG. 14.

The setting unit 1410 sets the processing conditions for performing the plasma processing (excluding the set frequency of the microwave) in each unit of the plasma processing apparatus 1, and further, notifies the inference unit 1420 of the processing conditions.

The inference unit 1420 includes a learned model 1421 generated by the learning unit 1210 in the learning phase. By inputting the processing conditions (excluding the set frequency of the microwave) notified by the setting unit 1410 into the learned model 1421, the inference unit 1420 infers the optimal set frequency that minimizes the power of the reflective wave.

Further, the inference unit 1420 instructs the microwave output device 16 to output the plasma generation microwave under the inferred set frequency.

### (2) Flow of Inference Process in Inference Phase

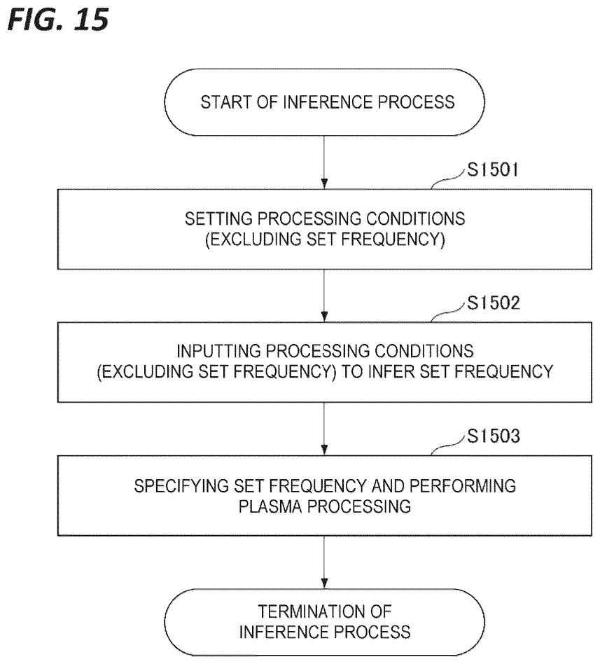

Next, the flow of the inference process by the control device 100 in the inference phase will be described. FIG. 15 is a flowchart illustrating the flow of the inference process.

In step S1501, the setting unit 1410 of the control device 100 acquires the processing conditions (excluding the set frequency of the microwave), and sets the processing conditions in each unit of the plasma processing apparatus 1, during the plasma processing.

In step S1502, the inference unit 1420 of the control device 100 inputs the acquired processing conditions (excluding the set frequency of the microwave) into the learned model 1421, to infer the set frequency.

In step S1503, the inference unit 1420 of the control device 100 instructs to perform the plasma processing under the inferred set frequency.

In this way, the control device 100 according to the present embodiment performs learning in advance, about the relationship between the processing conditions when the plasma processing is performed (excluding he set frequency of the microwave) and the set frequency that minimizes the power of the reflective wave, to generate the learned model. Then, the control device 100 according to the present embodiment infers the optimal set frequency using the learned model when performing the plasma processing.

As a result, according to the present embodiment, the set frequency of the radio frequency for generating plasma that minimizes the power of the reflective wave reflected from the processing space may be searched in a shorter time than that in the case of searching the set frequency during the plasma processing.

(Relationship between Set Frequency and Reflective Wave Characteristics)

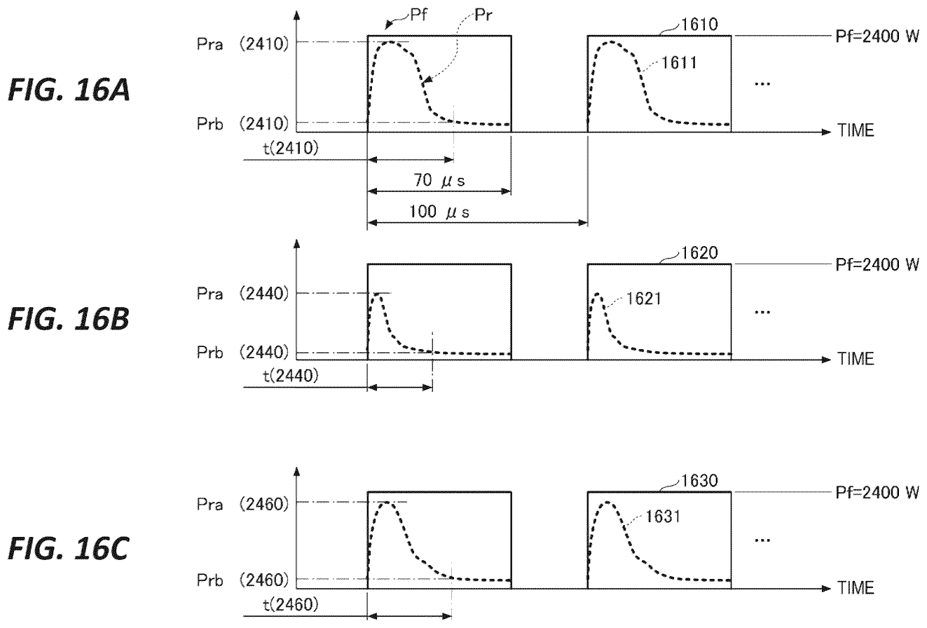

Next, prior to describing the details of the adjustment phase, the relationship between the set frequency inferred in the inference phase and the reflective wave characteristics is described. FIGS. 16A to 16C are views illustrating the relationship between the set frequency of the plasma generation microwave and the reflective wave characteristics.

In FIGS. 16A to 16C, the horizontal axis represents time, and the vertical axis represents the power of the microwave. In FIGS. 16A to 16C, the solid lines 1610, 1620, and 1630 represent pulse signals when the power of the microwave is pulse-modulated. The examples of FIGS. 16A to 16C represent
pulse frequency: 10 kHz
pulse duty ratio: 70%
power of traveling wave of microwave: 2,400 W.

In FIGS. 16A to 16C, the dotted lines 1611, 1621, and 1631 represent the power of the reflective wave of the microwave.

Further, FIGS. 16A to 16C represent the reflective wave characteristics in the case where the set frequencies of the plasma generation microwave are 2,410 MHz, 2,440 MHz, and 2,460 MHz, respectively. FIG. 16A represents that the following characteristics are acquired as the reflective wave characteristics:
Maximum reflection power at the start time of the pulse=Pᵣₐ (2,410)
Reflection power at the stable time of the pulse=P_{rb} (2,410)
Stable reflection time=t (2,410)

Similarly, FIG. 16B represents that the following characteristics are acquired as the reflective wave characteristics:
Maximum reflection power at the start time of the pulse=Pᵣₐ (2,440)
Reflection power at the stable time of the pulse=P_{rb} (2,440)
Stable reflection time=t (2,440)

Similarly, FIG. 16C represents that the following characteristics are acquired as the reflective wave characteristics:
Maximum reflection power at the start time of the pulse=Pᵣₐ (2,460)
Reflection power at the stable time of the pulse=P_{rb} (2,460)
Stable reflection time=t (2,460)

Thus, when the set frequency of the plasma generation microwave differs even though the processing conditions (excluding the set frequency of the microwave) are the same, the reflective wave characteristics differ. Therefore, in the adjustment phase, the set frequency inferred in advance by the learned model in the inference phase is finely adjusted according to the reflective wave characteristics measured during the execution of the plasma processing. Hereinafter, the control device 100 in the adjustment phase is described in detail.

### (Description of Control Device in Adjustment Phase)

Next, specific examples of the functional configuration and the process of the control device 100 in the adjustment phase are described.

### (1) Functional Configuration of Control Device in Adjustment Phase

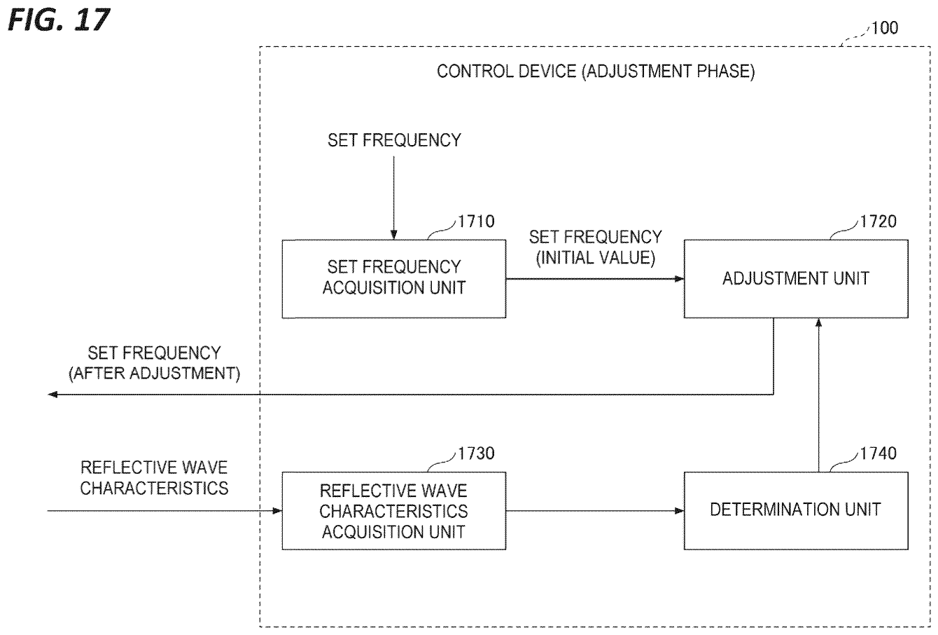

First, the functional configuration of the control device 100 in the adjustment phase is described. FIG. 17 is a view illustrating an example of the functional configuration of the control device in the adjustment phase. As described above, the plasma processing program is installed in the control device 100. By executing the program in the adjustment phase, the control device 100 functions as a set frequency acquisition unit 1710, an adjustment unit 1720, a reflective wave characteristics acquisition unit 1730, and a determination unit 1740, as illustrated in FIG. 17.

When the plasma processing is performed, the set frequency acquisition unit 1710 acquires the set frequency inferred in the inference phase, and notifies the acquired set frequency as an initial value to the adjustment unit 1720.

When the set frequency is notified as the initial value from the set frequency acquisition unit 1710, the adjustment unit 1720 calculates an adjusted set frequency that has been finely adjusted by adding k_{f} to the set frequency, and an adjusted set frequency that has been finely adjusted by subtracting k_{f} from the set frequency to decrease the reflective wave characteristics.

After the plasma processing is performed under the set frequency as the initial value for a predetermined time, the adjustment unit 1720 instructs to perform the plasma processing under each of the adjusted set frequencies for a predetermined time. The adjustment unit 1720 refers to results of a determination performed by the determination unit 1740 on the reflective wave characteristics acquired when the plasma processing is performed under the set frequency as the initial value and each of the adjusted set frequencies. When the determination unit 1740 determines that the fine adjustment is further necessary to decrease the reflective wave characteristics, the adjustment unit 1720 performs the same process as described above using the adjusted set frequency as an initial value. When the determination unit 1740 determines that the fine adjustment for decreasing the reflective wave characteristics is unnecessary, the adjustment unit 1720 terminates the adjustment phase.

The reflective wave characteristics acquisition unit 1730 acquires the reflective wave characteristics and notifies the acquired reflective characteristics to the determination unit 1740, each time the plasma processing is performed under an adjusted set frequency that has been finely adjusted by the adjustment unit 1720.

The determination unit 1740 determines whether the fine adjustment of the set frequency is necessary, based on the reflective wave characteristics notified from the reflective wave characteristics acquisition unit 1730.

### (2-1) Specific Example 1 of Adjustment Process

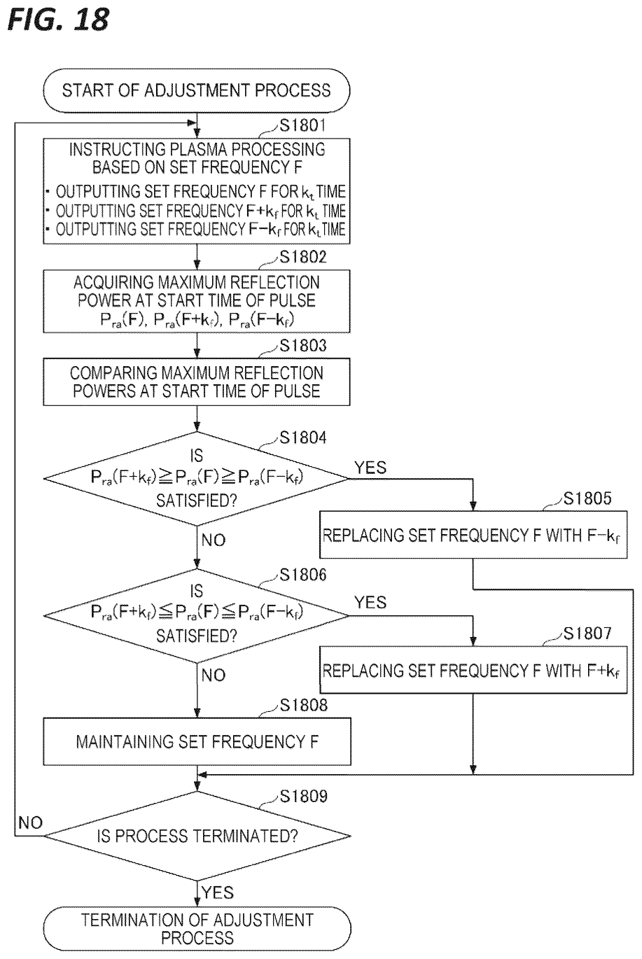

Next, a specific example of the adjustment process by the control device 100 is described. FIG. 17 is a first view illustrating a specific example of the adjustment process. In the adjustment phase, when the plasma processing apparatus 1 starts the plasma processing, the adjustment process illustrated in FIG. 18 starts.

In step S1801, the control device 100
outputs the microwave of the set frequency inferred in the inference phase for kₜ time,
outputs the microwave of the adjusted set frequency that has been finely adjusted by adding k_{f} to the set frequency inferred in the inference phase, for kₜ time, and
outputs the microwave of the adjusted set frequency that has been finely adjusted by subtracting k_{f} from the set frequency inferred in the inference phase, for kₜ time.

In step S1802, the control device 100 acquires the maximum reflection power Pᵣₐ(F) at the start time of the pulse when the microwave of the set frequency is output for kₜ time. Further, the control device 100 acquires the maximum reflection power Pᵣₐ(F+k_{f}) at the start time of the pulse when the microwave of the adjusted set frequency that has been finely adjusted by adding k_{f} to the set frequency is output for kₜ time. Further, the control device 100 acquires the maximum reflection power Pᵣₐ(F−k_{f}) at the start time of the pulse when the microwave of the adjusted set frequency that has been finely adjusted by subtracting k_{f} from the set frequency, is output for kₜ time.

In step S1803, the control device 100 compares the acquired maximum reflection powers at the start time of the pulse.

In step S1804, the control device 100 determines whether the relationship “Pᵣₐ(F+k_{f})≥Pᵣₐ(F)≥Pᵣₐ(F−k_{f})” is satisfied for the acquired maximum reflection powers at the start time of the pulse.

When it is determined in step S1804 that the relationship is satisfied (YES in step S1804), the process proceeds to step S1805. In step S1805, the control device 100 sets the value obtained by subtracting k_{f} from the set frequency as a new initial value, and proceeds with step S1809.

Meanwhile, when it is determined in step S1804 that the relationship is not satisfied (NO in step S1804), the process proceeds to step S1806.

In step S1806, the control device 100 determines whether the relationship “Pᵣₐ(F+k_{f})≤Pᵣₐ(F)≤Pᵣₐ(F−k_{f})” is satisfied for the acquired maximum reflection powers at the start time of the pulse.

When it is determined in step S1806 that the relationship is satisfied (YES in step S1806), the process proceeds to step S1807. In step S1807, the control device 100 sets the value obtained by adding k_{f} to the set frequency as a new initial value, and proceeds with step S1809.

Meanwhile, when it is determined in step S1806 that the relationship is not satisfied (NO in step S1806), the process proceeds to step S1808. In step S1808, the control device 100 determines that the inferred set frequency is maintained as an initial value, and proceeds with step S1809.

In step S1809, the control device 100 determines whether to terminate the adjustment process. When a new initial value is set in step S1805 or S1807, the control device 100 determines to continue the adjustment process (NO in step S1809), and returns to step S1801.

Meanwhile, when it is determined in step S1808 to maintain the inferred set frequency as an initial value, the control device 100 determines to terminate the adjustment process (YES in step S1809), and terminates the adjustment process.

### (2-2) Specific Example 2 of Adjustment Process

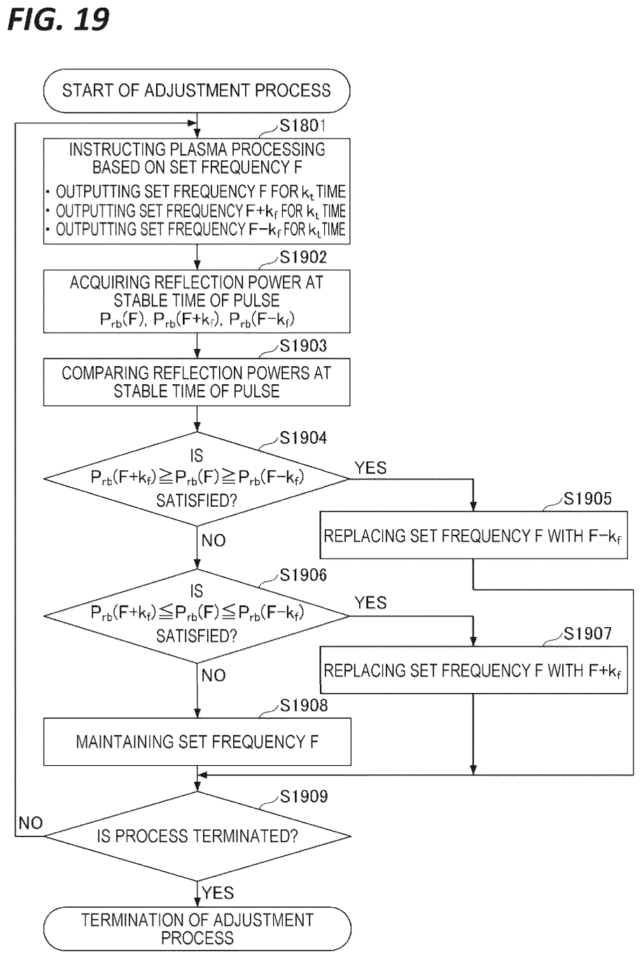

Next, another specific example of the adjustment process by the control device 100 will be described. FIG. 19 is a second view illustrating a specific example of the adjustment process. In the adjustment phase, when the plasma processing apparatus 1 starts the plasma processing, the adjustment process illustrated in FIG. 19 starts.

Since the process of step S1801 has been described using FIG. 18, the descriptions thereof are omitted here.

In step S1902, the control device 100 acquires the reflection power Pᵣₑ(F) at the stable time of the pulse when the microwave of the set frequency is output for kₜ time. Further, the control device 100 acquires the reflection power P_{rb}(F+k_{f}) at the stable time of the pulse when the microwave of the adjusted set frequency that has been finely adjusted by adding k_{f} to the set frequency is output for kₜ time. Further, the control device 100 acquires the reflection power Pᵣₑ(F−k_{f}) at the stable time of the pulse when the microwave of the adjusted set frequency that has been finely adjusted by subtracting k_{f} from the set frequency is output for kₜ time.

In step S1903, the control device 100 compares the acquired reflection powers at the stable time of the pulse.

In step S1904, the control device 100 determines whether the relationship “P_{rb}(F+k_{f})≥P_{rb}(F)≥P_{rb}(F−k_{f})” is satisfied for the acquired reflection powers at the stable time of the pulse.

When it is determined in step S1904 that the relationship is satisfied (YES in step S1904), the process proceeds to step S1905. In step S1905, the control device 100 sets the value obtained by subtracting k_{f} from the set frequency as a new initial value, and proceeds with step S1909.

Meanwhile, when it is determined in step S1904 that the relationship is not satisfied (NO in step S1904), the control device 100 proceeds with step S1906.

In step S1906, the control device 100 determines whether the relationship “P_{rb}(F+k_{f})≤P_{rb}(F)≤Pᵣₑ(F−k_{f})” is satisfied for the acquired reflection powers at the stable time of the pulse.

When it is determined in step S1906 that the relationship is satisfied (YES in step S1906), the process proceeds to step S1907. In step S1907, the control device 100 sets the value obtained by adding k_{f} to the set frequency as a new initial value, and proceeds with step S1909.

Meanwhile, when it is determined in step S1906 that the relationship is not satisfied (NO in step S1906), the process proceeds to step S1908. In step S1908, the control device 100 determines to maintain the inferred set frequency as an initial value, and proceeds with step S1909.

In step S1909, the control device 100 determines whether to terminate the adjustment process. When a new initial value is set in step S1905 or S1907, the control device 100 determines to continue the adjustment process (NO in step S1909), and returns to step S1901.

Meanwhile, when it is determined in step S1908 to maintain the inferred set frequency as an initial value, the control device 100 determines to terminate the adjustment process (YES in step S1909), and terminates the adjustment process.

### (2-3) Specific Example 3 of Adjustment Process

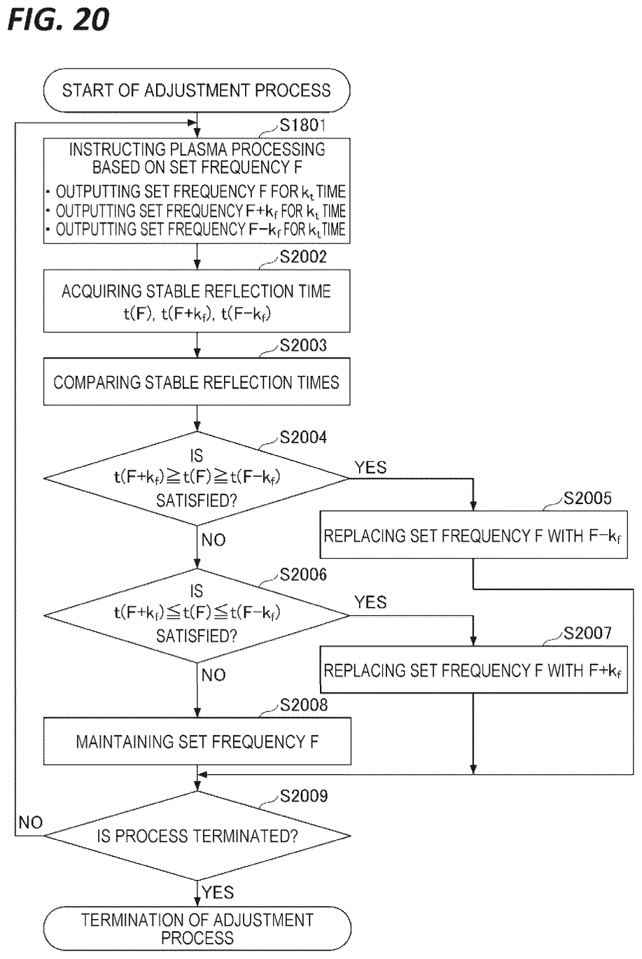

Next, yet another specific example of the adjustment process by the control device 100 is described. FIG. 20 is a third view illustrating a specific example of the adjustment process. In the adjustment phase, when the plasma processing apparatus 1 starts the plasma processing, the adjustment process illustrated in FIG. 20 starts.

Since the process of step S1801 has been described using FIG. 18, the descriptions thereof are omitted here.

In step S2002, the control device 100 acquires the stable reflection time t(F) when the microwave of the set frequency is output for kₜ time. Further, the control device 100 acquires the stable reflection time t(F+k_{f}) when the microwave of the adjusted set frequency that has been finely adjusted by adding k_{f} to the set frequency is output for kₜ time. Further, the control device 100 acquires the stable reflection time (F−k_{f}) when the microwave of the adjusted set frequency that has been finely adjusted by subtracting k_{f} from the set frequency is output for kₜ time.

In step S2003, the control device 100 compares the acquired stable reflection times.

In step S2004, the control device 100 determines whether the relationship “t(F+k_{f})≥t(F)≥t(F−k_{f})” is satisfied for the acquired stable reflection times.

When it is determined in step S2004 that the relationship is satisfied (YES in step S2004), the process proceeds to step S2005. In step S2005, the control device 100 sets the value obtained by subtracting k_{f} from the set frequency as a new initial value, and proceeds with step S2009.

Meanwhile, when it is determined in step S2004 that the relationship is not satisfied (NO in step S2004), the process proceeds to step S2006.

In step S2006, the control device 100 determines whether the relationship “t(F+k_{f})≤t(F)≤t(F−k_{f})” is satisfied for the acquired stable reflection times.

When it is determined in step S2006 that the relationship is satisfied (YES in step S2006), the process proceeds to step S2007. In step S2007, the control device 100 sets the value obtained by adding k_{f} to the set frequency as a new initial value, and proceeds with step S2009.

Meanwhile, when it is determined in step S2006 that the relationship is not satisfied (NO in step S2006), the process proceeds to step S2008. In step S2008, the control device 100 determines that the inferred set frequency is maintained as an initial value, and proceeds with step S2009.

In step S2009, the control device 100 determines whether to terminate the adjustment process. When a new initial value is set in step S2005 or S2007, the control device 100 determines to continue the adjustment process (NO in step S2009), and returns to step S2001.

Meanwhile, when it is determined in step S2008 to maintain the inferred set frequency as an initial value, the control device 100 determiners to terminate the adjustment process (YES in step S2009), and terminates the adjustment process.

### SUMMARY

As is clear from the descriptions above, the plasma processing apparatus 1 according to the first embodiment:
changes the set frequency of the plasma generation microwave when the plasma processing is performed under each of a plurality of processing conditions, to search for a set frequency that minimizes the power of the reflective wave reflected from the processing space. Further, the plasma processing apparatus 1 generates the learning data including the searched set frequency and a processing condition corresponding to the set frequency (excluding the set frequency of the microwave).
performs a model learning using the generated learning data to generate a learned model.
inputs processing conditions for performing the plasma processing into the learned model, to infer the set frequency of the plasma generation microwave.
performs the plasma processing under the inferred set frequency to measure the reflective wave characteristics, and finely adjust the inferred set frequency.

Thus, according to the first embodiment, it is possible to search for the set frequency of the plasma generation microwave that minimizes the power of the reflective wave reflected from the processing space, in a shorter time.

### Second Embodiment

In the first embodiment above, FIG. 5 illustrates a specific example of the plasma generation microwave output by the microwave output device 16 and a specific example of the bias radio frequency output by the radio-frequency power supply 58. However, the specific example of the plasma generation microwave output by the microwave output device 16 and the specific example of the bias radio frequency output by the radio-frequency power supply 58 are not limited to those illustrated in FIG. 5.

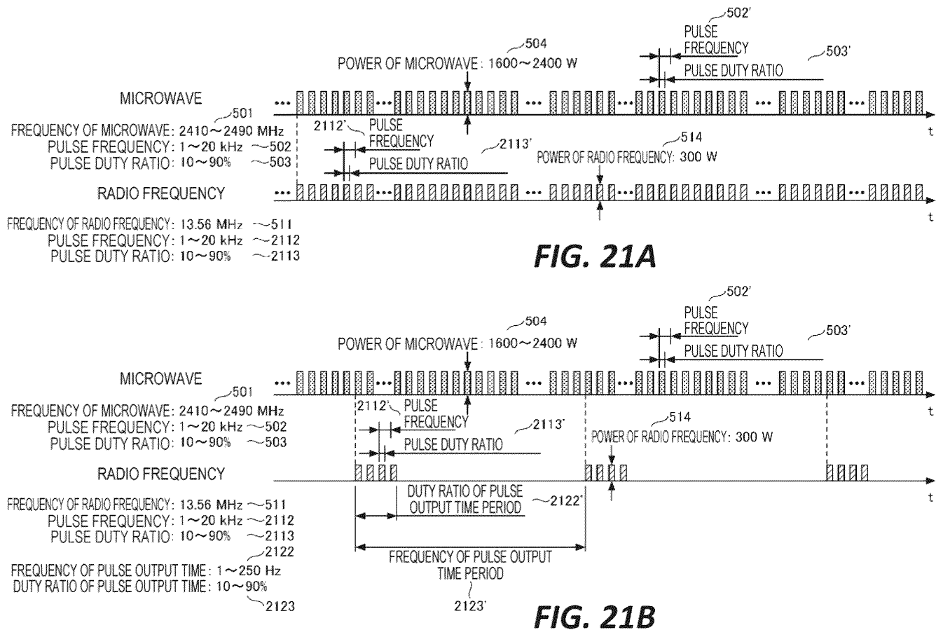

FIGS. 21A and 21B are second views illustrating examples of the plasma generation microwave and the bias radio frequency. FIG. 21A illustrates an example where a higher pulse frequency than that in FIG. 5 and a higher pulse duty ratio than that in FIG. 5 are set, when the radio-frequency power supply 58 outputs the bias radio frequency (see, e.g., the reference numerals 2112′ and 2113′).

FIG. 21B illustrates an example where a higher pulse frequency than that in FIG. 5 and a higher pulse duty ratio than that in FIG. 5 are set, when the radio-frequency power supply 58 outputs the bias radio frequency (reference numerals 2112′ and 2113′). Further, FIG. 21B illustrates an example where a pulse output time period and a pulse non-output time period are set, and the frequency of the pulse output time period is set to any one of 1 Hz to 250 Hz (see, e.g., the reference numeral 2122), when the radio-frequency power supply 58 outputs the bias radio frequency.

Further, FIG. 21B illustrates an example where the percentage of the pulse output time period is set to any one of 10% to 90% (see, e.g., the reference numeral 2123).

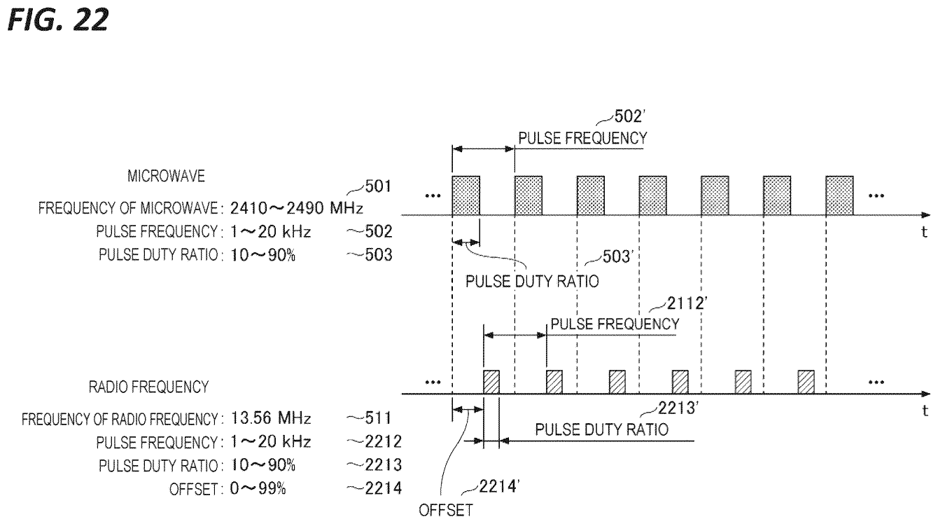

FIG. 22 is a third view illustrating an example of the plasma generation microwave and the bias radio frequency. FIG. 22 illustrates an example where a higher pulse frequency than that in FIG. 5 and a higher pulse duty ratio than that in FIG. 5 are set, when the radio-frequency power supply 58 outputs the bias radio frequency (see, e.g., the reference numerals 2212′ and 2213′). Further, FIG. 22 illustrates an example where an offset of any one of 0% to 99% is set for the pulse of the microwave output by the microwave output device 16, when the radio-frequency power supply 58 outputs the bias radio frequency (see, e.g., the reference numeral 2214).

As described above, the plasma generation microwave output by the microwave output device 16 and the bias radio frequency output by the radio-frequency power supply 58 are not limited to those illustrated in FIG. 5, and various cases of pulse signals may be assumed.

### Other Embodiments

In each of the embodiments above, the reflection coefficient Γ_{load} is described as an index used for stabilizing the plasma in the plasma processing, but instead of the reflection coefficient Γ_{load}, the power Pᵣ of the reflective wave of the microwave may be used as an index.

In each of the embodiments above, during the adjustment process, the following reflective wave characteristics are compared, and the comparison result is determined:
the reflective wave characteristics when the plasma processing is performed under the inferred set frequency,
the reflective wave characteristics when the plasma processing is performed under the adjusted set frequency that has been adjusted by adding k_{f} to the inferred set frequency, and
the reflective wave characteristics when the plasma processing is performed under the adjusted set frequency that has been adjusted by subtracting k_{f} from the inferred set frequency

However, the determination method during the adjustment process is not limited thereto, and it may be determined whether any one of the reflective wave characteristics has been improved.

In each of the embodiments above, FIG. 2 illustrates the method of measuring the power P_{f} of the traveling wave of the microwave and the power Pᵣ of the reflective wave of the microwave. However, the method of measuring the power P_{f} of the traveling wave of the microwave and the power Pᵣ of the reflective wave of the microwave is not limited thereto, and other measurement methods (see, e.g., Japanese Patent Laid-Open Publication No. 2016-170940) may be used.

In each of the embodiments above, the control device 100 is provided in the plasma processing apparatus 1. However, among the functions implemented by the control device 100, for example, the functions implemented in the learning phase and/or the inference phase may be provided as separate devices from the plasma processing apparatus 1.

When the functions implemented in the learning phase and/or the inference phase are provided as separate devices from the plasma processing apparatus 1, the devices functions as analysis devices, that provide the optimal set frequency when the plasma processing is performed in the plasma processing apparatus 1. In this case, the analysis devices execute the analysis program to implement the functions of the learning phase and/or the inference phase, and the control device of the plasma processing apparatus 1 executes the plasma processing program to implement the functions of the inference phase and/or the adjustment phase.

In each of the embodiments above, the microwave is used as the radio frequency for generating plasma. However, the radio frequency for generating plasma is not limited to the microwave.

The technology of the present disclosure may include the following aspects.

(Appendix 1) A plasma processing apparatus including:
an inference circuitry that infers a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

(Appendix 2) The plasma processing apparatus described in Appendix 1, further including:
an adjustment circuitry that adjusts the set frequency inferred by the inference circuitry, based on characteristics of the reflective wave reflected from the processing space by outputting the radio frequency for generating plasma under the set frequency inferred by the inference circuitry.

(Appendix 3) The plasma processing apparatus described in Appendix 1 or 2, wherein each of the plurality of processing conditions includes a setting for a pressure in the processing space, a setting for a type of gas supplied into the processing space, a setting for the radio frequency for generating plasma, and a setting for a radio frequency for bias.

(Appendix 4) The plasma processing apparatus described in any one of Appendixes 1 to 3, wherein the set frequency that minimizes the power of the reflective wave reflected from the processing space is a set frequency that minimizes a reflection coefficient calculated based on the power of the reflective wave, or a set frequency that minimizes a moving average value of the reflection coefficient calculated based on the power of the reflective wave in a predetermined frequency width.

(Appendix 5) The plasma processing apparatus described in any one of Appendixes 1 to 4, wherein the set frequency that minimizes the power of the reflective wave reflected from the processing space is a set frequency that minimizes a gradient of the reflection coefficient calculated based on the power of the reflective wave with respect to a predetermined frequency width, or a set frequency that minimizes a gradient of a moving average value of the reflection coefficient calculated based on the power of the reflective wave with respect to the predetermined frequency width.

(Appendix 6) The plasma processing apparatus described in any one of Appendixes 2 to 5, wherein the characteristics of the reflective wave include any one of a maximum reflection power at a start time of a pulse, a reflection power at a stable time of a pulse, and a stable reflection time.

(Appendix 7) The plasma processing apparatus described in any one of Appendixes 1 to 6, further including:
a generation circuitry that generates the learning data including the set frequency that minimizes the power of the reflective wave reflected from the processing space and the processing condition corresponding to the set frequency, the set frequency being searched by changing the set frequency of the radio frequency for generating plasma when the plasma processing is performed under each of the plurality of processing conditions; and
a learning circuitry that performs a model learning using the learning data generated by the generation circuitry, thereby generating the learned model.

(Appendix 8) An analysis apparatus including:
a generation circuitry that generates learning data including a set frequency that minimizes power of a reflective wave reflected from a processing space and a processing condition corresponding to the set frequency, the set frequency being searched by changing a set frequency of a plasma generation radio frequency when a plasma processing is performed under each of a plurality of processing conditions; and
a learning circuitry that performs a model learning using the learning data generated by the generation circuitry, thereby generating a learned model.

(Appendix 9) The analysis apparatus described in Appendix 8, further including:
an inference circuitry that infers the set frequency of the radio frequency for generating plasma, by inputting a processing condition for performing a plasma processing into the learned model.

(Appendix 10) The analysis apparatus described in any one of Appendix 8 or 9, wherein the plurality of processing conditions include a setting for a pressure in the processing space, a setting for a type of gas supplied into the processing space, a setting for the plasma generation radio frequency, and a setting for a bias radio frequency.

(Appendix 11) The analysis apparatus described in any one of Appendixes 8 to 10, wherein the set frequency that minimizes the power of the reflective wave reflected from the processing space is a set frequency that minimizes a reflection coefficient calculated based on the power of the reflective wave, or a set frequency that minimizes a moving average value of the reflection coefficient calculated based on the power of the reflective wave in a predetermined frequency width.

(Appendix 12) The analysis apparatus described in any one of Appendixes 8 to 10, wherein the set frequency that minimizes the power of the reflective wave reflected from the processing space is a set frequency that minimizes a gradient of the reflection coefficient calculated based on the power of the reflective wave with respect to a predetermined frequency width, or a set frequency that minimizes a gradient of a moving average value of the reflection coefficient calculated based on the power of the reflective wave with respect to the predetermined frequency width.

(Appendix 13) A plasma processing method including:
inferring a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

(Appendix 14) An analysis method including:
generating learning data including a set frequency that minimizes power of a reflective wave reflected from a processing space and a processing condition corresponding to the set frequency, the set frequency being searched by changing a set frequency of a radio frequency for generating plasma when a plasma processing is performed under each of a plurality of processing conditions; and
performing a model learning using the learning data generated in the generating, thereby generating a learned model.

(Appendix 15) A non-transitory computer-readable storage medium having stored therein a plasma processing program that causes a computer to execute a process including:
inferring a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

(Appendix 16) A non-transitory computer-readable storage medium having stored therein an analysis program that causes a computer to execute a process including:
generating learning data including a set frequency that minimizes power of a reflective wave reflected from a processing space and a processing condition corresponding to the set frequency, the set frequency being searched by changing a set frequency of a radio frequency for generating plasma when a plasma processing is performed under each of a plurality of processing conditions; and
performing a model learning using the learning data generated in the generating, thereby generating a learned model.

For the radio frequency for generating plasma, the set frequency that minimizes the power of the reflective wave reflected from the processing space may be searched in a relatively short time.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
an inference circuitry configured to infer a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

2. The plasma processing apparatus according to claim 1, further comprising:
an adjustment circuitry configured to adjust the set frequency inferred by the inference circuitry, based on characteristics of the reflective wave reflected from the processing space by outputting the radio frequency for generating plasma under the set frequency inferred by the inference circuitry.

3. The plasma processing apparatus according to claim 1, wherein each of the plurality of processing conditions includes a setting for a pressure in the processing space, a setting for a type of gas supplied into the processing space, a setting for the radio frequency for generating plasma, and a setting for a radio frequency for bias.

4. The plasma processing apparatus according to claim 1, wherein the set frequency that minimizes the power of the reflective wave reflected from the processing space is a set frequency that minimizes a reflection coefficient calculated based on the power of the reflective wave, or a set frequency that minimizes a moving average value of the reflection coefficient calculated based on the power of the reflective wave in a predetermined frequency width.

5. The plasma processing apparatus according to claim 1, wherein the set frequency that minimizes the power of the reflective wave reflected from the processing space is a set frequency that minimizes a gradient of the reflection coefficient calculated based on the power of the reflective wave with respect to a predetermined frequency width, or a set frequency that minimizes a gradient of a moving average value of the reflection coefficient calculated based on the power of the reflective wave with respect to the predetermined frequency width.

6. The plasma processing apparatus according to claim 2, wherein the characteristics of the reflective wave include any one of a maximum reflection power at a start time of a pulse, a reflection power at a stable time of a pulse, and a stable reflection time.

7. The plasma processing apparatus according to claim 1, further comprising:
a generation circuitry configured to generate the learning data including the set frequency that minimizes the power of the reflective wave reflected from the processing space and the processing condition corresponding to the set frequency, the set frequency being searched by changing the set frequency of the radio frequency for generating plasma when the plasma processing is performed under each of the plurality of processing conditions; and
a learning circuitry configured to perform a model learning using the learning data generated by the generation circuitry, thereby generating the learned model.

8. An analysis apparatus comprising:
a generation circuitry configured to generate learning data including a set frequency that minimizes power of a reflective wave reflected from a processing space and a processing condition corresponding to the set frequency, the set frequency being searched by changing a set frequency of a plasma generation radio frequency when a plasma processing is performed under each of a plurality of processing conditions; and
a learning circuitry configured to perform a model learning using the learning data generated by the generation circuitry, thereby generating a learned model.

9. The analysis apparatus according to claim 8, further comprising:
an inference circuitry configured to infer the set frequency of the radio frequency for generating plasma, by inputting a processing condition for performing a plasma processing into the learned model.

10. The analysis apparatus according to claim 8, wherein the plurality of processing conditions include a setting for a pressure in the processing space, a setting for a type of gas supplied into the processing space, a setting for the plasma generation radio frequency, and a setting for a bias radio frequency.

11. The analysis apparatus according to claim 8, wherein the set frequency that minimizes the power of the reflective wave reflected from the processing space is a set frequency that minimizes a reflection coefficient calculated based on the power of the reflective wave, or a set frequency that minimizes a moving average value of the reflection coefficient calculated based on the power of the reflective wave in a predetermined frequency width.

12. The analysis apparatus according to claim 8, wherein the set frequency that minimizes the power of the reflective wave reflected from the processing space is a set frequency that minimizes a gradient of the reflection coefficient calculated based on the power of the reflective wave with respect to a predetermined frequency width, or a set frequency that minimizes a gradient of a moving average value of the reflection coefficient calculated based on the power of the reflective wave with respect to the predetermined frequency width.

13. A plasma processing method comprising:
inferring a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

14. An analysis method comprising:
generating learning data including a set frequency that minimizes power of a reflective wave reflected from a processing space and a processing condition corresponding to the set frequency, the set frequency being searched by changing a set frequency of a radio frequency for generating plasma when a plasma processing is performed under each of a plurality of processing conditions; and
performing a model learning using the learning data generated in the generating, thereby generating a learned model.

15. A non-transitory computer-readable storage medium having stored therein a plasma processing program that causes a computer to execute a process including:
inferring a set frequency of a radio frequency for generating plasma by inputting a processing condition for performing a plasma processing into a learned model that has been trained using learning data including the set frequency that minimizes power of a reflective wave reflected from a processing space and a processing condition corresponding to the set frequency, the set frequency being searched by changing the set frequency of the radio frequency for generating plasma when a plasma processing is performed under each of a plurality of processing conditions.

16. A non-transitory computer-readable storage medium having stored therein an analysis program that causes a computer to execute a process including:
generating learning data including a set frequency that minimizes power of a reflective wave reflected from a processing space and a processing condition corresponding to the set frequency, the set frequency being searched by changing a set frequency of a radio frequency for generating plasma when a plasma processing is performed under each of a plurality of processing conditions; and
performing a model learning using the learning data generated in the generating, thereby generating a learned model.
